(19) United States
(12) Patent Application Publication
(10) Pub. No.: US 2012/0211729 A1
(43) Pub. Date: Aug. 23, 2012

(54) POLYMER LIGHT-EMITTING DEVICE

(75) Inventor: Shohgo Yamauchi, Tsukuba-shi (JP)

(73) Assignee: SUMITOMO CHEMICAL COMPANY, LIMITED, Chuo-ku, Tokyo (JP)

(21) Appl. No.: 13/386,975

(22) PCT Filed: Jul. 7, 2010
(86) PCT No.: PCT/JP2010/061516

§ 371 Date: May 7, 2012

(30) Foreign Application Priority Data
Jul. 31, 2009 (JP) 2009-178764

(51) Int. Cl. H01L 51/54

(52) U.S. Cl. 257/40; 257/E51.026

(57) ABSTRACT

The problem to be solved of the present invention is to provide a polymer light-emitting device having a long luminance half-decay lifetime. Means for solving the problem is a polymer light-emitting device in which the cathode comprises a first cathode layer and a second cathode layer in this order from a light-emitting layer side, the first cathode layer contains one or more metal compounds selected from the group consisting of sodium fluoride, potassium fluoride, rubidium fluoride and cesium fluoride, and the second cathode layer contains one or more metals selected from the group consisting of alkaline earth metals and aluminum, and in which a functional layer between an anode and the light-emitting layer contains a polymer compound including a repeating unit represented by the formula (1):

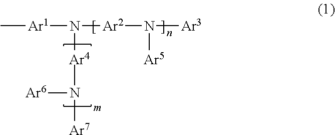

wherein Ar¹, Ar², Ar³ and Ar⁴ represent an arylene group or a divalent heterocyclic group, Ar⁵, Ar⁶ and Ar⁷ represent an aryl group or a monovalent heterocyclic group, n and m represent 0 or 1, and when n is 0, a carbon atom contained in Ar¹, may be directly bound to a carbon atom contained in Ar³, or may be bound to a carbon atom contained in Ar³ via an oxygen atom or a sulfur atom.

### TECHNICAL FIELD

The present invention relates to a polymer light-emitting device, and particularly to a polymer light-emitting device having a long light emission lifetime.

### BACKGROUND ART

An organic light-emitting device is a device configured to include a cathode, an anode and a layer of an organic light-emitting compound arranged between the cathode and the anode. In this device, the organic light-emitting compound recombines electrons supplied from the cathode with holes supplied from the anode. Energy generated thereby is taken out of the device as light.

As an example of the organic light-emitting device, a device in which the organic light-emitting compound is a polymer compound (hereinafter, referred to as a “polymer light-emitting device”) is known. The polymer light-emitting device is advantageous for enlargement of area of the device and reduction in cost since the light-emitting layer thereof can be conveniently formed by wet coating.

In the field of the organic light-emitting device, there is an object of lowering driving voltage and improving luminance of emission. In order to achieve this object, it is effective to improve efficiency of electron injection. Thus, various cathode structures aimed at facilitating injection of electrons into the light-emitting layer are investigated. For example, Patent Document 1 describes that a cathode used for the organic light-emitting device is formed into a two-layer structure having a metal compound layer and a metal layer. As the metal compound and the metal, lithium fluoride and aluminum are used, respectively.

Further, Patent Document 2 describes a cathode including a reduction reaction part formed by reduction reaction of a metal compound of an alkali metal or an alkaline earth metal with a reducing agent, and a transparent conductive film disposed on the reduction reaction part.

### BACKGROUND DOCUMENTS

### Patent Documents

Patent Document 1: Japanese Patent Laid-open Publication No. 1110 (1998)-74586
Patent Document 2: Japanese Patent Laid-open Publication No. 2004-311403

### DISCLOSURE OF THE INVENTION

### Problems to be Solved by the Invention

However, in the case of using these conventional cathode structures in the polymer light-emitting devices, there was a problem that the luminance half-decay lifetime is not sufficient.

It is an object of the present invention to provide a polymer light-emitting device having a long luminance half-decay lifetime.

### Means for Solving the Problems

That is, the present invention provides a polymer light-emitting device including a cathode, an anode, and a functional layer containing a polymer compound and a light-emitting layer containing an organic polymer light-emitting compound arranged between the cathode and the anode, wherein

the cathode comprises a first cathode layer and a second cathode layer in this order from the light-emitting layer side, the first cathode layer contains one or more metal compounds selected from the group consisting of sodium fluoride, potassium fluoride, rubidium fluoride and cesium fluoride, and the second cathode layer contains one or more metals selected from the group consisting of alkaline earth metals and aluminum, and wherein

the polymer compound contained in the functional layer is a polymer compound including a repeating unit represented by the formula (1):

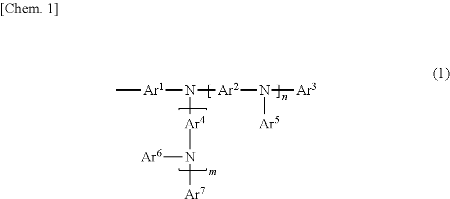

wherein Ar¹, Ar², and Ar⁴ are the same or different and each represent an arylene group optionally having a substituent or a divalent heterocyclic group optionally having a substituent, Ar⁵, Ar⁶ and Ar⁷ are the same or different and each represent an aryl group optionally having a substituent or a monovalent heterocyclic group optionally having a substituent, n and m are the same or different and each represent 0 or 1, and when n is 0, a carbon atom contained in Ar¹ may be directly bound to a carbon atom contained in Ar³, or may be bound to a carbon atom contained in Ar³ via an oxygen atom or a sulfur atom.

In one embodiment, the polymer compound contained in the functional layer is an organic polymer compound further including a repeating unit having a structure represented by the formula:

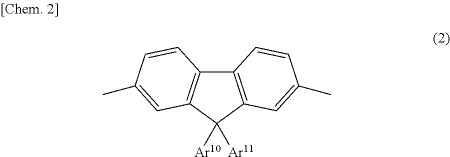

wherein Ar¹⁰ and Ar¹¹ are the same or different and each represent an alkyl group, an aryl group optionally having a substituent or a monovalent heterocyclic group optionally having a substituent.

In one embodiment, the alkaline earth metal is magnesium or calcium.

In one embodiment, the cathode comprises a first cathode layer, a second cathode layer and a third cathode layer in this order from the light-emitting layer side, the second cathode layer contains one or more alkaline earth metals selected from the group consisting of magnesium and calcium, and the third cathode layer is made of a conductive substance.

In one embodiment, the film thickness of the first cathode layer is not less than 0.5 nm and less than 6 nm.

In one embodiment, the functional layer is a hole transporting layer disposed between the anode and the light-emitting layer, and the polymer compound is a hole transporting compound.

In one embodiment, m and n each represent 0, and Ar¹, Ar³ and Ar⁷ are the same or different from one another and represent a phenyl group optionally having a substituent.

In one embodiment, Ar¹⁰ and Ar¹¹ are the same or different and each represent an alkyl group having 5 to 8 carbon atoms.

Further, the present invention provides a polymer light-emitting display comprising the polymer light-emitting device according to any one of the above-mentioned paragraphs as a pixel unit.

### Effects of the Invention

The polymer light-emitting device of the present invention is very useful industrially since it has a low driving voltage to start light emission and a long luminance half-decay lifetime.

### BRIEF DESCRIPTION OF THE DRAWINGS

FIG. 1 is a schematic sectional view showing a structure of an organic EL device, which is one embodiment of the present invention.

FIG. 2 is a schematic sectional view showing a structure of an organic EL device, which is another embodiment of the present invention.

### EMBODIMENT FOR CARRYING OUT THE INVENTION

### 1. Structure of Device

A polymer light-emitting device of the present invention includes a cathode, an anode, and a light-emitting layer containing an organic polymer light-emitting compound arranged between the cathode and the anode. Further, the polymer light-emitting device of the present invention further includes at least one functional layer containing a polymer compound arranged between the cathode and the anode.

Examples of the functional layer include a hole injection layer, a hole transporting layer, an electron injection layer, an electron transporting layer, a hole blocking layer and an interlayer and the like. For example, from the viewpoint of lowering driving voltage when light is emitted at a luminance of 1000 cd/m² and from the viewpoint of lengthening the luminance half-decay lifetime, it is preferred that the polymer light-emitting device has the functional layer between the anode and the light-emitting layer, and it is more preferred that the functional layer is the hole transporting layer. In this case, the hole transporting compound contained in the hole transporting layer is preferably an organic polymer compound having a repeating unit represented by the formula (1).

As described above, the polymer light-emitting device of the present invention includes the cathode and the anode, and includes at least the functional layer and the light-emitting layer arranged between the cathode and the anode, and in addition to these, the polymer light-emitting device can further include an optional constituent.

For example, when the functional layer is the hole transporting layer, the polymer light-emitting device can include the hole injection layer between the anode and the hole transporting layer, and can further include the interlayer between the light-emitting layer and the hole injection layer (when the hole injection layer is present) or the anode (when the hole injection layer is absent).

On the other hand, the polymer light-emitting device can include the electron injection layer between the cathode and the light-emitting layer, and can further include one or more of the electron transporting layer and the hole blocking layer between the light-emitting layer and the electron injection layer (when the electron injection layer is present) or the cathode (when the electron injection layer is absent).

Here, the anode supplies a hole to the hole injection layer, the hole transporting layer, the interlayer, the light-emitting layer and the like, and the cathode supplies an electron to the electron injection layer, the electron transporting layer, the hole blocking layer, the light-emitting layer and the like.

The light-emitting layer refers to a layer having a function capable of injecting a hole from a layer adjacent to an anode and injecting an electron from a layer adjacent to a cathode in applying an electrical field, a function of moving injected charges (electron and hole) by a force of the electrical field, and a function of providing a field for binding between the electron and the hole and leading this binding to light emission.

The electron injection layer and the electron transporting layer refer to a layer having any one of a function of injecting an electron from the cathode, a function of transporting an electron and a function of blocking a hole injected from the anode. Further, the hole blocking layer refers to a layer having a function of primarily blocking a hole injected from the anode, and further having either of a function of injecting an electron from the cathode and a function of transporting an electron, as required.

The hole injection layer and the hole transporting layer refer to a layer having any one of a function of injecting a hole from the anode, a function of transporting a hole, a function of supplying a hole to the light-emitting layer and a function of damming an electron injected from the cathode. Further, the interlayer has at least one of a function of injecting a hole from the anode, a function of transporting a hole, a function of supplying a hole to the light-emitting layer and a function of blocking an electron injected from the cathode, is usually arranged at a position adjacent to the light-emitting layer, and has a function of isolating the light-emitting layer from the anode, or the light-emitting layer from the hole injection layer or the hole transporting layer.

Here, the electron transporting layer and the hole transporting layer are collectively called charge transporting layers. Further, the electron injection layer and the hole injection layer are collectively called charge injection layers.

The polymer light-emitting device of the present invention can be usually configured to further include a substrate as an optional constituent and to dispose the cathode, the anode, the functional layer and the light-emitting layer on the surface of the substrate, and other optional constituents as required.

In an aspect of the polymer light-emitting device of the present invention, usually, the anode is disposed on the substrate, and as an upper layer thereof, the functional layer and the light-emitting layer are laminated, and as an additional upper layer thereof, the cathode is laminated. As a variation of the aspect, it is also possible to employ an aspect in which the cathode is disposed on the substrate, and as an upper layer thereof, the functional layer and the light-emitting layer are laminated, and the anode is disposed as the upper layer of the functional layer and the light-emitting layer.

As another variation, it is also possible to employ a polymer light-emitting device of any of the so-called bottom emission type to emit light from a substrate side, the so-called top emission type to emit light from a side opposite to the substrate side and a both-side light emission type.

As further variation, a layer having other functions such as optional protective film, buffer film, reflective layer and the like may be disposed. The polymer light-emitting device is further covered with a sealing film or a sealing substrate to form a polymer light-emitting apparatus in which the polymer light-emitting device is isolated from the outside air.

For example, the polymer light-emitting device of the present invention can have the following layer structure (a), or can have a layer structure in which one or more layers of the hole injection layer, the hole transporting layer, the interlayer, the hole blocking layer, the electron transporting layer and the electron injection layer are omitted from the layer structure (a). Further, in the polymer light-emitting device of the present invention, the functional layer functions as any one layer of the hole injection layer, the hole transporting layer, the interlayer, the hole blocking layer, the electron transporting layer and the electron injection layer.

(a) anode-hole injection layer-(hole transporting layer and/or interlayer)-light-emitting layer-(hole blocking layer and/or electron transporting layer)-electron injection layer-cathode

Herein, with respect to the symbol “-”, for example, “layer A-layer B” means that the layer A is adjacently laminated to the layer B.

The term “(hole transporting layer and/or interlayer)” refers to a layer composed only of the hole transporting layer, a layer composed only of the interlayer, a layer configuration of hole transporting layer-interlayer, a layer configuration of interlayer-hole transporting layer, or other arbitrary layer configurations including one or more hole transporting layers and interlayers, respectively.

The term “(hole blocking layer and/or electron transporting layer)” refers to a layer composed only of the hole blocking layer, a layer composed only of the electron transporting layer, a layer configuration of hole blocking layer-electron transporting layer, a layer configuration of electron transporting layer-hole blocking layer, or other arbitrary layer configurations including one or more hole blocking layers and electron transporting layers, respectively. In the following, layer configurations will be described similarly to these descriptions.

Moreover, the polymer light-emitting device of the present invention can have two light-emitting layers in one laminate structure. In this case, the polymer light-emitting device can have the following layer structure (b), or can have a layer structure in which one or more layers of the hole injection layer, the hole transporting layer, the interlayer, the hole blocking layer, the electron transporting layer, the electron injection layer and the electrode are omitted from the layer structure (b).

(b) anode-hole injection layer-(hole transporting layer and/or interlayer)-light-emitting layer-(hole blocking layer and/or electron transporting layer)-electron injection layer-electrode-hole injection layer-(hole transporting layer and/or interlayer)-light-emitting layer-(hole blocking layer and/or electron transporting layer)-electron injection layer-cathode

Moreover, the polymer light-emitting device of the present invention can have three or more light-emitting layers in one laminate structure. In this case, the polymer light-emitting device can have the following layer structure (c), or can have a layer structure in which one or more layers of the hole injection layer, the hole transporting layer, the interlayer, the hole blocking layer, the electron transporting layer, the electron injection layer and the electrode are omitted from the layer structure (c).

(c) anode-hole injection layer-(hole transporting layer and/or interlayer)-light-emitting layer-(hole blocking layer and/or electron transporting layer)-electron injection layer-repeating unit A-repeating unit A . . . -cathode

Here, the “repeating unit A” represents a unit of the layer structure of electrode-hole injection layer-(hole transporting layer and/or interlayer)-light-emitting layer-(hole blocking layer and/or electron transporting layer)-electron injection layer.

Preferable specific examples of the layer structure of the polymer light-emitting device of the present invention are as follows.

(e) anode-hole transporting layer-light-emitting layer-cathode
(f) anode-light-emitting layer-electron transporting layer-cathode
(g) anode-hole transporting layer-light-emitting layer-electron transporting layer-cathode

Further, for each of these structures, a structure in which the interlayer is disposed at a position adjacent to the light-emitting layer between the light-emitting layer and the anode is exemplified. That is, the following structures (d′) to (g′) are exemplified.

(d′) anode-interlayer-light-emitting layer-cathode
(e′) anode-hole transporting layer-interlayer-light-emitting layer-cathode
(f′) anode-interlayer-light-emitting layer-electron transporting layer-cathode
(g′) anode-hole transporting layer-interlayer-light-emitting layer-electron transporting layer-cathode

In the present invention, examples of a polymer light-emitting device including a charge injection layer (electron injection layer or hole injection layer) include a polymer light-emitting device in which the charge injection layer is disposed at a position adjacent to the cathode, and a polymer light-emitting device in which the charge injection layer is disposed at a position adjacent to the anode. Specific examples thereof include the following structures (h) to (s).

(h) anode-charge injection layer-light-emitting layer-cathode
(i) anode-light-emitting layer-charge injection layer-cathode
(j) anode-charge injection layer-light-emitting layer-charge injection layer-cathode
(k) anode-charge injection layer-hole transporting layer-light-emitting layer-cathode
(l) anode-hole transporting layer-light-emitting layer-charge injection layer-cathode
(m) anode-charge injection layer-hole transporting layer-light-emitting layer-charge injection layer-cathode
(n) anode-charge injection layer-light-emitting layer-electron transporting layer-cathode
(o) anode-light-emitting layer-electron transporting layer-charge injection layer-cathode
(p) anode-charge injection layer-light-emitting layer-electron transporting layer-charge injection layer-cathode
(q) anode-charge injection layer-hole transporting layer-light-emitting layer-electron transporting layer-cathode
(r) anode-hole transporting layer-light-emitting layer-electron transporting layer-charge injection layer-cathode
(s) anode-charge injection layer-hole transporting layer-light-emitting layer-electron transporting layer-electron injection layer-cathode

Further, for each of these layer structures, a structure in which the interlayer is disposed at a position adjacent to the light-emitting layer between the light-emitting layer and the anode similarly to the above-mentioned (d′) to (g′) is exemplified. In this case, the interlayer may also serve as the hole injection layer and/or the hole transporting layer.

The polymer light-emitting device of the present invention may further include an insulating layer at a position adjacent to the electrode for the purpose of improving adhesion to the electrode or improving charge (i.e., hole or electron) injection performance from the electrode, or may further include a thin buffer layer located at the interface between the charge transporting layer (i.e., hole transporting layer or electron transporting layer) and another layer or between the light-emitting layer and another layer for the purpose of improving adhesion of the interface or preventing material mixing between the organic layers.

The order and the number of layers to be laminated, and thickness of each layer can be appropriately determined in consideration of luminous efficiency or a device lifetime.

### 2. Materials Composing Layers of Device

Next, materials of and methods for forming layers composing the polymer light-emitting device of the present invention will be described more specifically.

<Cathode>

In the present invention, the cathode is disposed directly on the light-emitting layer or disposed with any layer interposed between the cathode and the light-emitting layer. The cathode is composed of two or more layers, and herein, these are referred to as a first cathode layer, a second cathode layer, . . . in this order from a side close to the light-emitting layer. The first cathode layer is a metal compound layer containing a metal compound and the second cathode layer is a metal layer containing a metal.

In the present invention, the first cathode layer contains one or more materials selected from the group consisting of sodium fluoride, potassium fluoride, rubidium fluoride and cesium fluoride, is preferably made of one or more materials selected from the group consisting of sodium fluoride, potassium fluoride, rubidium fluoride and cesium fluoride, and is more preferably made of sodium fluoride or potassium fluoride.

In the present invention, the material contained in the second cathode layer preferably has a reduction action on the alkali metal fluoride composing the first cathode layer. The presence or absence and level of a reducing power between materials can be estimated, for example, from bond dissociation energy) (ΔrH°) between compounds. That is, in the reduction reaction of the material composing the first layer by the material contained in the second layer, if ΔrH° is a positive combination, it can be said that the material contained in the second layer has a reducing power on the material composing the first layer. Even if ΔrH° is negative, when the absolute value thereof is small, the material contained in the second layer, which has become thermally active during a process for film-forming a cathode, such as a vacuum deposition method and the like, can have a reducing power on the material composing the first layer. For the bond dissociation energy, “Electrochemical Handbook (5th edition)” (Maruzen Publishing Co., Ltd., 2000), “Thermodynamic Database MALT” (Kagaku Gijutsu-Sha, 1992) and the like can be referred to.

When the strength of a chemical bond of the alkali metal fluoride composing the first cathode layer and/or the layer thickness of the first cathode layer is large, it is preferred that a material having a high reducing power is used as the material contained in the second cathode layer, and/or concentration of the material having a reducing power in the second cathode layer is increased.

The second cathode layer contains one or more materials selected from the group consisting of alkaline earth metals and aluminum, and is preferably made of one or more materials selected from the group consisting of alkaline earth metals and aluminum. Among these, magnesium, calcium and aluminum are preferred, and magnesium and aluminum are more preferred. It is preferred that the alkaline earth metal is magnesium or calcium.

When the second cathode layer contains a substance vulnerable to oxidation like magnesium or calcium, or when the thickness of the second cathode layer is small and therefore sufficient conductivity for an electrode cannot be secured, a conductive substance can be further laminated on the second cathode layer optionally as a third cathode layer. By doing so, an effect of protecting the second cathode layer from oxidation is achieved, or it becomes possible to ensure sufficient conductivity for an electrode.

Specific examples of conductive substances include metals with low resistance such as gold, silver, copper, aluminum, chromium, tin, lead, nickel, titanium and the like, and alloys containing these metals; conductive metal oxides such as tin oxide, zinc oxide, indium oxide, indium tin oxide (ITO), indium zinc oxide (IZO), molybdenum oxide and the like; and mixtures of these conductive metal oxides and metals, and the like.

Examples of a preferred combination of the materials of the cathode layer include a combination of a first cathode layer being sodium fluoride and a second cathode layer being aluminum, a combination of a first cathode layer being potassium fluoride and a second cathode layer being aluminum, a combination of a first cathode layer being rubidium fluoride and a second cathode layer being aluminum, a combination of a first cathode layer being cesium fluoride and a second cathode layer being aluminum, a combination of a first cathode layer being sodium fluoride and a second cathode layer being a magnesium-silver alloy, a combination of a first cathode layer being potassium fluoride and a second cathode layer being a magnesium-silver alloy, a combination of a first cathode layer being rubidium fluoride and a second cathode layer being a magnesium-silver alloy, a combination of a first cathode layer being cesium fluoride and a second cathode layer being a magnesium-silver alloy, a combination of a first cathode layer being sodium fluoride, a second cathode layer being calcium and a third cathode layer being aluminum, a combination of a first cathode layer being sodium fluoride, a second cathode layer being magnesium and a third cathode layer being aluminum, a combination of a first cathode layer being sodium fluoride, a second cathode layer being aluminum and a third cathode layer being silver, and a combination of a first cathode layer being potassium fluoride, a second cathode layer being aluminum and a third cathode layer being silver, and the like.

Layer thickness (D1) of the first cathode layer preferably satisfies 0.5 nm≦D1<6 nm. When D1 is less than 0.5 nm, amount of the alkali metal fluoride may be insufficient, and therefore there may be cases where the first cathode layer cannot exert the ability to inject an electron, and when D1 is more than 6 nm, the reduction of the first cathode layer material by a material contained in the second cathode layer may be insufficient, and therefore there may be cases where the first cathode layer cannot exert the ability to inject an electron. D1 more preferably satisfies 1.0 nm<D1<5.0 nm, and for example, when the combination of the materials of the cathode layer is a combination of a first cathode layer being sodium fluoride and a second cathode layer being aluminum, good performance of injecting an electron and a good luminance half-decay lifetime can be attained by determining D1 so as to satisfy 2.0 nm≦D1≦4.0 nm.

Film thickness (D1) of the first cathode layer and film thickness (D2) of the second cathode layer preferably satisfy D1≦D2 from the viewpoint of adequately covering the first cathode layer with the second cathode layer. When D2 is smaller than D1, the reduction of the first cathode layer material by a material contained in the second cathode layer may be insufficient, and therefore there may be cases where the first cathode layer cannot exert the ability to inject an electron.

A method for preparing the cathode is not particularly limited and publicly known methods can be employed. Examples thereof include a vacuum deposition method, a sputtering method, an ion plating method and the like. When metals, metal oxides, metal fluorides, or metal carbonates are used, a vacuum deposition method is often used, and when conductive metal oxides such as metal oxides having a high boiling point, composite metal oxides, indium tin oxide (ITO) and the like are used, a sputtering method, an ion plating method and the like is often used. When a mixed composition of these materials and a different material is formed into a film, a co-deposition method, a sputtering method, an ion plating method or the like is used. Particularly, when a mixed composition of a low molecular organic substance and a metal, a metal oxide, a metal fluoride or a metal carbonate is formed into a film, the co-deposition method is suitable.

When a light-transmitting electrode is used as the cathode in the polymer light-emitting device of the present invention, visible light transmittance of the third and more cathode layers is 40% or more, and preferably 50% or more. Such a visible light transmittance is attained by using, as a cathode layer material, a transparent conductive metal oxide such as indium tin oxide (ITO), indium zinc oxide (IZO) or molybdenum oxide, or by maintaining film thickness of a cover cathode layer, which uses a metal with low resistance such as gold, silver, copper, aluminum, chromium, tin, lead and the like, and an alloy containing these metals, below 30 nm.

Further, an antireflection layer may be disposed on an outermost layer of the cathode for the purpose of improving transmittance in the case where light having entered from the light-emitting layer side passes through the cathode and exits the cathode. As a material used in the antireflection layer, a material having a refractive index of about 1.8 to 3.0 is preferred, and examples of the material include zinc sulfide, zinc selenide, tungsten oxide (WO₃) and the like. Film thickness of the antireflection layer varies depending on the combination of the materials, and is usually in the range of 10 nm to 150 nm.

<Substrate>

The substrate composing the polymer light-emitting device of the present invention may be a substance which does not vary when the electrode is formed and a layer of an organic substance is formed, and for example, glass, plastic, a polymer film, a metal film, a silicon substrate, a laminate thereof and the like is used. As the substrate, commercialized products are available, or the substrate can be produced by a publicly known method.

When the polymer light-emitting device of the present invention composes pixels of the display, a circuit for driving pixels may be disposed on the substrate, or a planarizing film may be disposed on the driving circuit. When the planarizing film is disposed, average roughness (Ra) at the center line on the planarizing film preferably satisfies Ra<10 nm.

Ra can be measured according to Japanese Industrial Standards JIS-B0601-2001 by reference to JIS-B0651 to JIS-B0656 and JIS-B0671-1 and the like.

<Anode>

In the anode composing the polymer light-emitting device of the present invention, it is preferred that work function of the surface on the light-emitting layer side of the anode is 4.0 eV or more from the viewpoint of the ability to supply a hole to an organic semiconductor material to be used in the hole injection layer, the hole transporting layer, the interlayer, the light-emitting layer and the like. Electroconductive compounds such as metals, alloys, metal oxides and metal sulfides and the like, or mixtures thereof and the like can be used for the material of the anode. Specific examples of the electroconductive compounds include conductive metal oxides such as tin oxide, zinc oxide, indium oxide, indium tin oxide (ITO), indium zinc oxide (IZO), molybdenum oxide and the like; or metals such as gold, silver, chromium, nickel and the like; and mixtures of these conductive metal oxides and metals and the like.

The anode may have a single-layer structure composed of one or more of these materials, or may have a multilayer structure composed of a plurality of layers having the same composition or different compositions. When the anode has a multilayer structure, a material having a work function of 4.0 eV or more is preferably used for the outermost surface layer of the light-emitting layer side of the anode

A method for preparing the anode is not particularly limited and publicly known methods can be employed. Examples thereof include a vacuum deposition method, a sputtering method, an ion plating method, a plating method and the like.

The film thickness of the anode is usually 10 nm to 10 μm, and preferably 50 nm to 500 nm. Further, average roughness (Ra) at the center line on the surface on the light-emitting layer side of the anode preferably satisfies Ra<10 nm, and more preferably Ra<5 nm from the viewpoint of preventing defective electrical connection such as short circuit and the like.

Moreover, after the anode is prepared by the above-mentioned method, it may be surface-treated with UV ozone, a silane coupling agent, a solution containing an electron-accepting compound such as 2,3,5,6-tetrafluoro-7,7,8,8-tetracyanoquinodimethane and the like, and the like. By the surface treatment, electrical connection to the organic layer in contact with the anode is improved.

When the anode is used as a light-reflecting electrode in the polymer light-emitting device of the present invention, the anode preferably has a multilayer structure in which a light-reflecting layer composed of a highly light-reflecting metal is combined with a high work function material layer containing a material having a work function of 4.0 eV or more.

Specific examples of such a configuration of the anode are as follows:

### (i) Ag—MoO₃,

(Ag—Pd—Cu alloy)-(ITO and/or IZO),
(Al—Nd alloy)-(ITO and/or IZO),
(iv) (Mo—Cr alloy)-(ITO and/or IZO),
(v) (Ag—Pd—Cu alloy)-(ITO and/or IZO)-MoOhd 3, and the like.
In order to attain sufficient light reflectance, film thickness of the highly light-reflecting metal layer such as Al, Ag, an Al alloy, an Ag alloy, a Cr alloy and the like is preferably 50 nm or more, and more preferably 80 nm or more. Film thickness of the high work function material layer such as ITO, IZO, MoO₃ and the like is usually in the range of 5 to 500 nm.

<Hole Injection Layer>

Examples of materials composing the hole injection layer in the polymer light-emitting device of the present invention include carbazole derivatives, triazole derivatives, oxazole derivatives, oxadiazole derivatives, imidazole derivatives, polyarylalkane derivatives, pyrazoline derivatives, pyrazolone derivatives, phenylenediamine derivatives, arylamine derivatives, starburst type amines, phthalocyanine derivatives, amino-substituted chalcone derivatives, styrylanthracene derivatives, fluorenone derivatives, hydrazone derivatives, stilbene derivatives, silazane derivatives, aromatic tertiary amine compounds, styrylamine compounds, aromatic dimethylidyne-based compounds, porphyrin-based compounds, polysilane-based compounds, poly(N-vinylcarbazole) derivatives, organic silane derivatives, and polymers containing these. Further, examples of materials composing the hole injection layer also include conductive metal oxides such as vanadium oxide, tantalum oxide, tungsten oxide, molybdenum oxide, ruthenium oxide, aluminum oxide and the like; conductive polymers and oligomers such as polyaniline, aniline-based copolymers, a thiophene oligomer, polythiophene and the like; organic conductive materials such as poly(3,4-ethylenedioxythiophene)-polystyrenesulfonic acid, polypyrrole and the like, and polymers containing these; polymer compounds including a repeating unit represented by the formula (1); and amorphous carbon and the like. Moreover, accepting organic compounds such as tetracyanoquinodimethane derivatives (e.g., 2,3,5,6-tetrafluoro-7,7,8,8-tetracyanoquinodimethane), 1,4-naphthoquinone derivatives, diphenoquinone derivatives, polynitro compounds and the like; and silane coupling agents such as octadecyltrimethoxysilane and the like can be suitably used.

The above-mentioned materials may be a single component, or may be a composition including a plurality of components. Further, the hole injection layer may have a single-layer structure composed of one or more of the above-mentioned materials, or may have a multilayer structure composed of a plurality of layers having the same composition or different compositions. Further, the materials, which are exemplified as the materials capable of being used in a hole transporting layer or an interlayer, can also be used in the hole injection layer.

A method for preparing the hole injection layer is not particularly limited and publicly known methods can be employed. Examples thereof include a vacuum deposition method, a sputtering method, an ion plating method and the like for the inorganic compound materials, and include a vacuum deposition method, transfer methods such as laser transfer, thermal transfer and the like, methods based on film formation from a solution (a mixed solution of a low molecular organic material and a polymer binder may be employed) and the like for low molecular organic materials. Further, in the case of polymer organic materials, examples of the method for preparing the hole injection layer include methods based on film formation from a solution.

The hole injection layer can be prepared by use of the vacuum deposition method when the hole injection material is a low molecular compound such as a pyrazoline derivative, an arylamine derivative, a stilbene derivative, a triphenyldiamine derivative and the like.

Further, the hole injection layer can also be formed by use of a mixed solution in which a polymer compound binder and these low molecular hole injection materials are dispersed. As the polymer compound binder mixed in the mixed solution, a substance not extremely interfering with charge transfer is preferable, and a substance not having intense absorption of visible light is suitably used. Specific examples thereof include poly(N-vinylcarbazole), polyaniline or derivatives thereof, polythiophene or derivatives thereof, poly(p-phenylene vinylene) or derivatives thereof, poly(2,5-thienylene vinylene) or derivatives thereof, polycarbonate, polyacrylate, polymethyl acrylate, polymethyl methacrylate, polystyrene, polyvinyl chloride, polysiloxane and the like.

A solvent for use in forming a film from a solution is not particularly limited as long as it is a solvent which dissolves the hole injection material. Examples of the solvent include water; chlorine-based solvents such as chloroform, methylene chloride, dichloroethane and the like; ether-based solvents such as tetrahydrofuran and the like; aromatic hydrocarbon-based solvents such as toluene, xylene and the like; ketone-based solvents such as acetone, methyl ethyl ketone and the like; and ester-based solvents such as ethyl acetate, butyl acetate, ethyl cellosolve acetate and the like.

As a method for forming a film from a solution, application methods which include coating methods such as a spin coating method from a solution, a casting method, a microgravure coating method, a gravure coating method, a bar coating method, a roller coating method, a wire-bar coating method, a dip coating method, a slit coating method, a capillary coating method, a spray coating method, a nozzle coating method and the like; and printing methods such as a gravure printing method, a screen printing method, a flexo printing method, an offset printing method, a reversal printing method, an ink-jet printing method and the like, can be used. The printing method such as a gravure printing method, a screen printing method, a flexo printing method, an offset printing method, a reversal printing method, an ink-jet printing method and the like; and the nozzle coating method are preferable in that pattern forming is easy.

When the organic compound layer such as the hole transporting layer, the interlayer, the light-emitting layer and the like is formed following the hole injection layer, particularly when both of the hole injection layer and a layer laminated thereon are formed by an application method, a layer applied first may be dissolved in a solvent contained in a solution of a layer to be applied later, resulting in failure in preparation of a laminate structure. In this case, it is possible to employ a method of making the lower layer insoluble in the solvent. Examples of the method of making the lower layer insoluble in the solvent include a method of crosslinking by attaching a crosslinking group to the polymer compound itself, a method of crosslinking by mixing a low molecular compound containing a crosslinkable group having an aromatic ring typified by aromatic bisazide with a crosslinking agent, a method of crosslinking by mixing a low molecular compound containing a crosslinkable group not having an aromatic ring typified by an acrylate group with a crosslinking agent, a method of making the lower layer insoluble in an organic solvent to be used for preparation of the upper layer by exposing the lower layer to ultraviolet light, a method of making the lower layer insoluble in an organic solvent to be used for preparation of the upper layer by heating the lower layer, and the like. Heating temperature in heating the lower layer is usually about 100° C. to 300° C., and heating time is usually about 1 minute to 1 hour.

As another method of laminating without dissolving the lower layer by a method other than crosslinking, there is a method of using solutions having different polarities for layers adjacent to each other, and examples thereof include a method in which a water-soluble polymer compound is used for the lower layer, a oil-soluble polymer compound is used for the upper layer, thereby making the lower layer not soluble even if the upper layer material is applied, and the like.

Film thickness of the hole injection layer varies in an optimal value depending on a material to be used, and may be selected in such a way that driving voltage and luminous efficiency are moderate, but it is necessary to select such a thickness that at least no pinhole is produced. When the thickness is too large, it is not preferred since driving voltage of a device is high. Therefore, film thickness of the hole injection layer is, for example, 1 nm to 1 μm, preferably 2 nm to 500 nm, and moreover preferably 10 nm to 100 nm.

<Hole Transporting Layer or Interlayer>

Examples of materials composing the hole transporting layer or the interlayer in the polymer light-emitting device of the present invention include carbazole derivatives, triazole derivatives, oxazole derivatives, oxadiazole derivatives, imidazole derivatives, polyarylalkane derivatives, pyrazoline derivatives, pyrazolone derivatives, phenylenediamine derivatives, arylamine derivatives, amino-substituted chalcone derivatives, styrylanthracene derivatives, fluorenone derivatives, hydrazone derivatives, stilbene derivatives, silazane derivatives, aromatic tertiary amine compounds, styrylamine compounds, aromatic dimethylidyne-based compounds, porphyrin-based compounds, polysilane-based compounds, poly(N-vinylcarbazole) derivatives, organic silane derivatives, and polymer compounds containing these structures. Further, examples of materials composing the hole transporting layer or the interlayer also include conductive polymers and oligomers such as aniline-based copolymers, thiophene oligomers, polythiophene and the like; and organic conductive materials such as polypyrrole and the like.

The above-mentioned materials may be a single component, or may be a composition including a plurality of components. Further, the hole transporting layer or the interlayer may have a single-layer structure composed of one or more of the above-mentioned materials, or may have a multilayer structure composed of a plurality of layers having the same composition or different compositions. Further, the materials, which are exemplified as the materials capable of being used in the hole injection layer, can also be used as the hole transporting layer.

Specifically, compounds disclosed in Japanese Patent Laid-open Publication No. S63 (1988)-70257, Japanese Patent Laid-open Publication No. S63 (1988)-175860, Japanese Patent Laid-open Publication No. 112 (1990)-135359, Japanese Patent Laid-open Publication No. 112 (1990)-135361, Japanese Patent Laid-open Publication No. 112 (1990)-209988, Japanese Patent Laid-open Publication No. H3 (1991)-37992, Japanese Patent Laid-open Publication No. 113 (1991)-152184, Japanese Patent Laid-open Publication No. H5 (1993)-263073, Japanese Patent Laid-open Publication No. H6 (1994)-1972, International Publication WO 2005/52027 and Japanese Patent Laid-open Publication No. 2006-295203 and the like, can be used as a material of the hole transporting layer or the interlayer. Among these, the polymer compound containing a repeating unit including a structure of an aromatic tertiary amine compound is suitably used.

The reason for this is that the luminance half-decay lifetime of the polymer light-emitting device is particularly lengthened by combining the cathode having the structure of the present invention with the hole transporting layer including the polymer compound containing a repeating unit including a structure of an aromatic tertiary amine compound.

Examples of the repeating units including a structure of an aromatic tertiary amine compound include the repeating unit represented by the formula (1).

In the formula (1), a hydrogen atom on the aromatic ring may be substituted with a substituent selected from halogen atoms, alkyl groups, alkyloxy groups, alkylthio groups, aryl groups, aryloxy groups, arylthio groups, arylalkyl groups, arylalkyloxy groups, arylalkylthio groups, alkenyl groups, alkynyl groups, arylalkenyl groups, arylalkynyl groups, acyl groups, acyloxy groups, amide groups, acid imide groups, imine residues, substituted amino groups, substituted silyl groups, substituted silyloxy groups, substituted silylthio groups, substituted silylamino groups, cyano groups, nitro groups, monovalent heterocyclic groups, heteroaryloxy groups, heteroarylthio groups, alkyloxycarbonyl groups, aryloxycarbonyl groups, arylalkyloxycarbonyl groups, heteroaryloxycarbonyl groups, carboxyl groups and the like.

Further, the substituent may be a crosslinkable group such as a vinyl group, an acetylene group, a butenyl group, an acrylic group, an acrylate group, an acrylamide group, a methacrylic group, a methacrylate group, a methacrylic amide group, a vinyl ether group, a vinylamino group, a silanol group, a group having a small-membered ring (e.g., a cyclopropyl group, a cyclobutyl group, an epoxy group, an oxetane group, a diketene group, and an episulfide group), a lactone group, a lactam group, a group including a structure of a siloxane derivative and the like. Further, in addition to the above-mentioned groups, combinations of groups capable of forming an ester bond or an amide bond (e.g., an ester group and an amino group, an ester group and a hydroxyl group) and the like can also be used as the crosslinkable group.

Moreover, a carbon atom contained in Ar² may be directly bound to a carbon atom contained in Ar³, or may be bound to a carbon atom contained in Ar³ via a divalent group such as —O—, —S— and the like.

Examples of the arylene group as Ar¹, Ar², Ar³ and Ar⁴ include a phenylene group and the like, and examples of the divalent heterocyclic group as Ar¹, Ar², Ar³ and Ar⁴ include a pyridinediyl group and the like. These groups optionally have a substituent.

Examples of the aryl group as Ar⁵, Ar⁶ and Ar⁷ include a phenyl group, a naphtyl group and the like, and examples of the monovalent heterocyclic group as Ar⁵, Ar⁶ and Ar⁷ include a pyridyl group and the like. These groups optionally have a substituent.

As the substituents, which the arylene group, the aryl group, the divalent heterocyclic group and the monovalent heterocyclic group may optionally have, an alkyl group, an alkyloxy group, and an aryl group are preferred, and the alkyl group is more preferred from the viewpoint of solubility of the polymer compound. Examples of the alkyl group include a methyl group, an ethyl group, a propyl group, an i-propyl group, a butyl group, an i-butyl group, a t-butyl group, a s-butyl group, a pentyl group, a hexyl group, a heptyl group, an octyl group and the like. Examples of the alkyloxy group include a methoxy group, an ethoxy group, a propyloxy group, an i-propyloxy group, a butyloxy group, an i-butyloxy group, a t-butyloxy group, a s-butyloxy group, a pentyloxy group, a hexyloxy group, a pentyloxy group, a hexyloxy group and the like.

Ar¹ to Ar⁴ are each preferably an arylene group, and more preferably a phenylene group from the viewpoint of the luminance half-decay lifetime of the polymer light-emitting device. Ar⁵ to Ar⁷ are each preferably an aryl group, and more preferably a phenyl group from the viewpoint of the luminance half-decay lifetime of the polymer light-emitting device.

From the viewpoint of ease of synthesis of a monomer, m and n are each preferably 0.

Specific examples of the repeating unit represented by the formula (1) include the following repeating units and the like.

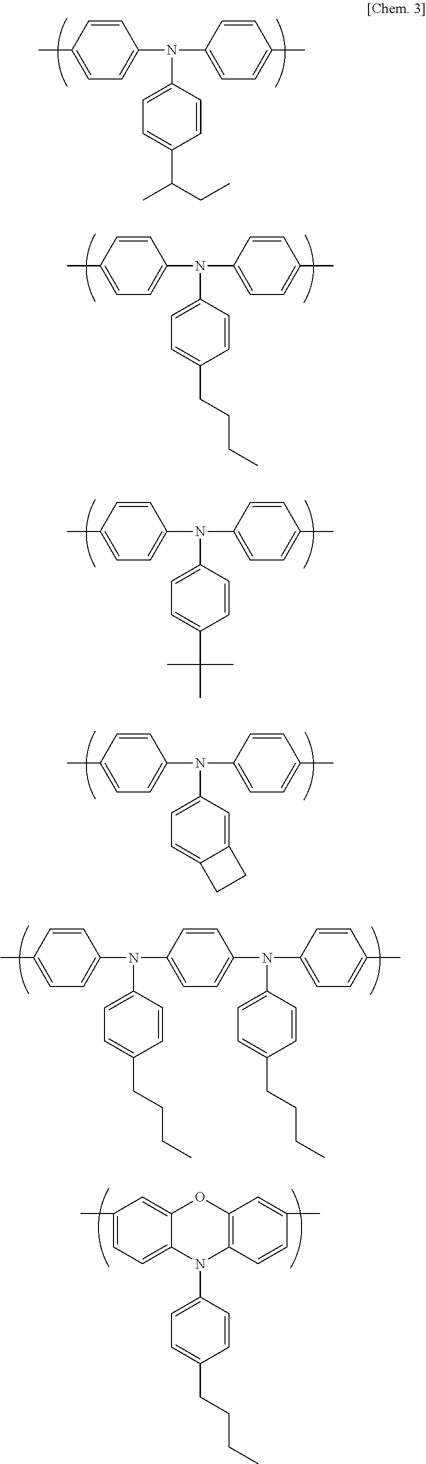

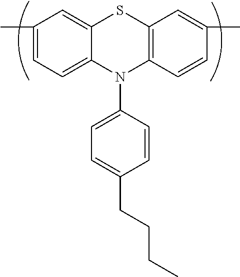

The polymer compound including a repeating unit represented by the formula (1) may further include other repeating units. Examples of the other repeating units include arylene groups and the like such as a phenylene group, a fluorenediyl group and the like, and the other repeating units are preferably a repeating unit represented by the formula (2) from the viewpoint of the luminance half-decay lifetime of the polymer light-emitting device.

In addition, among the polymer compound including a repeating unit represented by the formula (1), polymer compounds containing a crosslinkable group are more preferable.

As the substituents, which the aryl group and the monovalent heterocyclic group represented by Ar¹⁰ and Ar¹¹ in the formula (2) may optionally have, an alkyl group, an alkyloxy group, and an aryl group are preferred, and an alkyl group is more preferred from the viewpoint of solubility of the polymer compound. Examples of the alkyl group include a methyl group, an ethyl group, a propyl group, an i-propyl group, a butyl group, an i-butyl group, a t-butyl group, a s-butyl group, a pentyl group, a hexyl group, a heptyl group, an octyl group and the like. Examples of the alkyloxy group include a methoxy group, an ethoxy group, a propyloxy group, an i-propyloxy group, a butyloxy group, an i-butyloxy group, a t-butyloxy group, a s-butyloxy group, a pentyloxy group, a hexyloxy group, a pentyloxy group, a hexyloxy group and the like. Examples of the aryl group represented by Ar¹⁰ and Ar¹¹ include a phenyl group, a naphtyl group and the like, and examples of the monovalent heterocyclic group represented by Ar¹⁰ and Ar¹¹ include a pyridyl group and the like. These groups may have a substituent.

Specific examples of the repeating unit represented by the formula (2) include the following repeating units and the like.

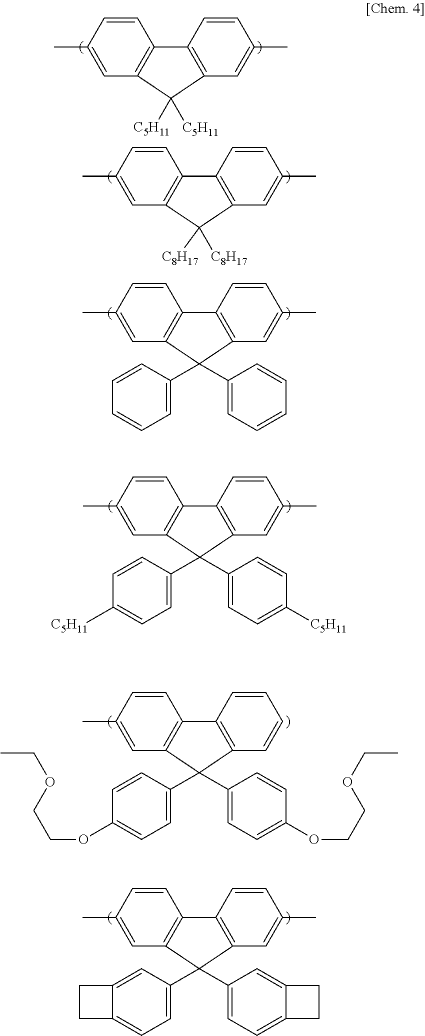

A method for forming the hole transporting layer or the interlayer is not particularly limited, and examples of the method include the same methods as in forming the hole injection layer. Examples of a method for forming a film from a solution include application methods and printing methods such as the above-mentioned spin coating method, casting method, bar coating method, slit coating method, spray coating method, nozzle coating method, gravure printing method, screen printing method, flexo printing method, ink-jet printing method and the like, and include a vacuum deposition method, a transfer method and the like for the case of using a sublimating compound material.

Examples of solvents for use in forming a film from a solution include the solvents exemplified in the method for forming a film of the hole injection layer.

When the organic compound layer such as the light-emitting layer and the like is formed by an application method following the hole transporting layer or the interlayer, if a lower layer is soluble in a solvent contained in a solution of a layer to be applied later, the lower layer can be made insoluble in the solvent by the method similar to that described in the method for producing a film of the hole injection layer.

The film thickness of the hole transporting layer or the interlayer varies in an optimal value depending on a material to be used, and may be selected in such a way that driving voltage and luminous efficiency are moderate, but it is necessary to select such a thickness that at least no pinhole is produced. When the thickness is too large, it is not preferred since driving voltage of a device is high. Therefore, the film thickness of the hole transporting layer or the interlayer is, for example, 1 nm to 1 μm, preferably 2 nm to 500 nm, and moreover preferably 5 nm to 100 nm.

<Light-Emitting Layer>

In the polymer light-emitting device of the present invention, the light-emitting layer contains an organic polymer light-emitting compound. As the organic polymer light-emitting compound, conjugated polymer compounds such as polyfluorene derivatives, poly(p-phenylenevinylene) derivatives, polyphenylene derivatives, poly(p-phenylene) derivatives, polythiophene derivatives, polydialkylfluorene, polyfluorenebenzothiadiazole, polyalkylthiophene and the like can be suitably used.

Further, the light-emitting layer containing these organic polymer light-emitting compounds may contain polymer-based dye compounds such as perylene-based dyes, coumarin-based dyes, rhodamine-based dyes and the like, or low molecular dye compounds such as rubrene, perylene, 9,10-diphenylanthracene, tetraphenylbutadiene, nile red, coumarin 6, quinacridone and the like. Further, the light-emitting layer may contain naphthalene derivatives, anthracene or derivatives thereof, perylene or derivatives thereof, dyes such as polymethine-based dyes, xanthene-based dyes, coumarin-based dyes, cyanine-based dyes and the like, metal complexes of 8-hydroxyquinoline or derivatives thereof, aromatic amines, tetraphenylcyclopentadiene or derivatives thereof, or tetraphenylbutadiene or derivatives thereof, and metal complexes emitting phosphorescence such as tris(2-phenylpyridine)iridium and the like.

Further, the light-emitting layer included in the polymer light-emitting device of the present invention may be composed of a mixed composition of an unconjugated polymer compound [e.g., polyvinylcarbazole, polyvinyl chloride, a polycarbonate, polystyrene, polymethyl methacrylate, polybutyl methacrylate, a polyester, polysulfone, polyphenyleneoxide, polybutadiene, poly(N-vinylcarbazole), a hydrocarbon resin, a ketone resin, a phenoxy resin, a polyamide, ethyl cellulose, an ABS resin, a polyurethane, a melamine resin, an unsaturated polyester resin, an alkyd resin; an epoxy resin or a silicone resin; or a polymer containing a polyarylalkane derivative, a polysilane-based compound, a poly(N-vinylcarbazole) derivative, vinyl acetate, a pyrazoline derivative, a pyrazolone derivative, a phenylenediamine derivative, an arylamine derivative, an amino-substituted chalcone derivative, a styrylanthracene derivative, a hydrazone derivative, a stilbene derivative, a silazane derivative, an aromatic tertiary amine compound, a styrylamine compound, an aromatic dimethylidyne-based compound, a porphyrin-based compound or an organic silane derivative] and a light-emitting organic compound such as the above-mentioned organic dye, metal complex and the like.

Specific examples of such polymer compounds include polyfluorene, or derivatives and copolymers thereof, polyarylene, or derivatives and copolymers thereof; polyarylene vinylene, or derivatives and copolymers thereof, and (co)polymers of aromatic amines or derivatives thereof, which are disclosed in WO 97/09394, WO 98/27136, WO 99/54385, WO 00/22027, WO 01/19834, GB 2340304 A, GB 2348316, U.S. Pat. No. 5,736,36, U.S. Pat. No. 5,741,921, U.S. Pat. No. 5,777,070, EP 0707020, Japanese Patent Laid-open Publication No. H9 (1997)-111233, Japanese Patent Laid-open Publication No. 1110 (1998)-324870, Japanese Patent Laid-open Publication No. 2000-80167, Japanese Patent Laid-open Publication No. 2001-123156, Japanese Patent Laid-open Publication No. 2004-168999 and Japanese Patent Laid-open Publication No. 2007-162009, and in “Development and Materials of Organic EL Device” (CMC Publishing Co., Ltd., 2006) and the like.

Further, specific examples of the low molecular dye compounds include compounds described in Japanese Patent Laid-open Publication No. S57 (1982)-51781, and “Data Book on Work Function of Organic Thin Films (2nd edition)” (CMC Publishing Co., Ltd., 2006) and “Development and Materials of Organic EL Device” (CMC Publishing Co., Ltd., 2006).

The above-mentioned materials may be a single component, or may be a composition including a plurality of components. Further, the light-emitting layer may have a single-layer structure composed of one or more of the above-mentioned materials, or may have a multilayer structure composed of a plurality of layers having the same composition or different compositions.

A method for forming the light-emitting layer is not particularly limited, and examples of the method include the same methods as in forming the hole injection layer. Examples of a method for forming a film from a solution include the above-mentioned application methods and printing methods such as a spin coating method, a casting method, a bar coating method, a slit coating method, a spray coating method, a nozzle coating method, a gravure printing method, a screen printing method, a flexo printing method, an ink-jet printing method and the like, and include a vacuum deposition method and a transfer method for the case of using a sublimating compound material.

Examples of solvents for use in forming a film from a solution include the solvents exemplified in the method for forming a film of the hole injection layer.

When the organic compound layer such as the electron transporting layer and the like is formed by an application method following the light-emitting layer, if a lower layer is soluble in a solvent contained in a solution of a layer to be applied later, the lower layer can be made insoluble in the solvent by the method similar to that described in the method for producing a film of the hole injection layer.

Film thickness of the light-emitting layer varies in an optimal value depending on a material to be used, and may be selected in such a way that driving voltage and luminous efficiency are moderate, but it is necessary to select such a thickness that at least no pinhole is produced. When the thickness is too large, it is not preferred since driving voltage of a device is high. Therefore, the film thickness of the light-emitting layer is, for example, 5 nm to 1 μm, preferably 10 nm to 500 nm, and more preferably 30 nm to 200 nm.

<Electron Transporting Layer or Hole Blocking layer>

As materials composing the electron transporting layer or the hole blocking layer in the polymer light-emitting device of the present invention, publicly known materials can be used, and examples thereof include triazole derivatives, oxazole derivatives, oxadiazole derivatives, imidazole derivatives, fluorenone derivatives, benzoquinone or derivatives thereof, naphthoquinone or derivatives thereof, anthraquinone or derivatives thereof, tetracyanoanthraquinodimethane or derivatives thereof, fluorenone derivatives, diphenyldicyano ethylene or derivatives thereof, diphenoquinone derivatives, anthraquinodimethane derivatives, anthrone derivatives, thiopyrandioxide derivatives, carbodiimide derivatives, fluorenylidene methane derivatives, distyrylpyrazine derivatives, tetracarboxylic acid anhydrides of aromatic rings such as naphthalene, perylene and the like, phthalocyanine derivatives, metal complexes of 8-quinolinol derivatives or metal phthalocyanines, various metal complexes typified by metal complexes containing benzooxazole or benzothiazole as a ligand, organic silane derivatives, polymer compounds including the repeating unit represented by the formula (1) and the like.

Among these, triazole derivatives, oxadiazole derivatives, benzoquinone or derivatives thereof, anthraquinone or derivatives thereof, metal complexes of 8-hydroxyquinoline or derivatives thereof, polyquinoline or derivatives thereof, polyquinoxaline or derivatives thereof, and polyfluorene or derivatives thereof are preferred.

The above-mentioned materials may be a single component, or may be a composition including a plurality of components. Further, the electron transporting layer or the hole blocking layer may have a single-layer structure composed of one or more of the above-mentioned materials, or may have a multilayer structure composed of a plurality of layers having the same composition or different compositions. Further, the materials, which are exemplified as the materials capable of being used in an electron injection layer, can also be used in the electron transporting layer or the hole blocking layer.

A method for forming the electron transporting layer or the hole blocking layer is not particularly limited, and examples of the method include the same methods as in forming the hole injection layer. Examples of a method for forming a film from a solution include the above-mentioned application methods and printing methods such as a spin coating method, a casting method, a bar coating method, a slit coating method, a spray coating method, a nozzle coating method, a gravure printing method, a screen printing method, a flexo printing method, an ink-jet printing method and the like, and include a vacuum deposition method, a transfer method and the like for the case of using a sublimating compound material.

Examples of solvents for use in forming a film from a solution include the solvents exemplified in the method for forming a film of the hole injection layer.

When the organic compound layer such as the electron injection layer and the like is formed by an application method following the electron transporting layer or the hole blocking layer, if a lower layer is soluble in a solvent contained in a solution of a layer to be applied later, the lower layer can be made insoluble in the solvent by the method similar to that described in the method for producing a film of the hole injection layer.

Film thickness of the electron transporting layer or the hole blocking layer varies in an optimal value depending on a material to be used, and may be selected in such a way that driving voltage and luminous efficiency are moderate, but it is necessary to select such a thickness that at least no pinhole is produced. When the thickness is too large, it is not preferred since driving voltage of a device is high. Therefore, the film thickness of the electron transporting layer or the hole blocking layer is, for example, 1 nm to 1 μm, preferably 2 nm to 500 nm, and more preferably 5 nm to 100 nm.

<Electron Injection Layer>

As materials composing the electron injection layer in the polymer light-emitting device of the present invention, publicly known materials can be used, and examples thereof include triazole derivatives, oxazole derivatives, oxadiazole derivatives, imidazole derivatives, fluorenone derivatives, benzoquinone or derivatives thereof, naphthoquinone or derivatives thereof, anthraquinone or derivatives thereof, tetracyanoanthraquinodimethane or derivatives thereof, fluorenone derivatives, diphenyldicyano ethylene or derivatives thereof, diphenoquinone derivatives, anthraquinodimethane derivatives, anthrone derivatives, thiopyrandioxide derivatives, carbodiimide derivatives, fluorenylidene methane derivatives, distyrylpyrazine derivatives, tetracarboxylic acid anhydrides of aromatic rings such as naphthalene, perylene and the like, phthalocyanine derivatives, metal complexes of 8-quinolinol derivatives or metal phthalocyanines, various metal complexes typified by metal complexes containing benzooxazole or benzothiazole as a ligand, organic silane derivatives and the like.

The above-mentioned materials may be a single component, or may be a composition including a plurality of components. Further, the electron injection layer may have a single-layer structure composed of one or more of the above-mentioned materials, or may have a multilayer structure composed of a plurality of layers having the same composition or different compositions. Further, the materials, which are exemplified as the materials capable of being used in the electron transporting layer or the hole blocking layer, can also be used in the electron injection layer.

A method for forming the electron injection layer is not particularly limited, and examples of the method include the same methods as in forming the hole injection layer. Examples of a method for forming a film from a solution include the above-mentioned application methods and printing methods such as a spin coating method, a casting method, a bar coating method, a slit coating method, a spray coating method, a nozzle coating method, a gravure printing method, a screen printing method, a flexo printing method, an ink-jet printing method and the like, and include a vacuum deposition method, a transfer method and the like for the case of using a sublimating compound material.

Examples of solvents for use in forming a film from a solution include the solvents exemplified in the method for forming a film of the hole injection layer.

Film thickness of the electron injection layer varies in an optimal value depending on a material to be used, and may be selected in such a way that driving voltage and luminous efficiency are moderate, but it is necessary to select such a thickness that at least no pinhole is produced. When the thickness is too large, it is not preferred since driving voltage of a device is high. Therefore, the film thickness of the electron injection layer is, for example, 1 nm to 1 μm, preferably 2 nm to 500 nm, and moreover preferably 5 nm to 100 nm.

<Insulating Layer>

The insulating layer having a film thickness of 5 nm or less, which the polymer light-emitting device of the present invention optionally include, has functions of improving adhesion to the electrode, improving charge (i.e., hole or electron) injection from the electrode, preventing mixing with an adjacent layer, and the like. Examples of the material of the insulating layer include metal fluorides, metal oxides, organic insulating materials (polymethyl methacrylate, etc.) and the like. Examples of the polymer light-emitting device provided with an insulating layer having a film thickness of 5 nm or less include one provided with an insulating layer having a film thickness of 5 nm or less adjacent to the cathode and one provided with an insulating layer having a film thickness of 5 nm or less adjacent to the anode.

### 3. Method for Producing Device

The method for producing a polymer light-emitting device of the present invention is not particularly limited and the polymer light-emitting device can be produced by laminating the respective layers successively on the substrate. Specifically, the anode is disposed on the substrate, thereon, the layers such as the hole injection layer, the hole transporting layer, the interlayer and the like are disposed as required, thereon, the light-emitting layer is disposed, thereon, the layers such as the electrode transporting layer, the electron injection layer and the like are disposed as required, and thereon, the cathode is laminated to produce a polymer light-emitting device.

### 4. Display

A polymer light-emitting display of the present invention comprises the above-mentioned polymer light-emitting device of the present invention as a pixel unit. An embodiment of the array of the pixel units is not particularly limited and can be an array commonly employed in displays such as television sets and the like, and can be an embodiment in which many pixels are arrayed on a common substrate. In the apparatus of the present invention, the pixels arrayed on a substrate can be formed within a pixel region defined by a bank as required.

The apparatus of the present invention can further include a sealing member on a side opposite to a substrate side of the light-emitting layer so that the light-emitting layer and the like are sandwiched, as required. Further, the apparatus of the present invention can further include any constituent for composing a display, for example, filters such as a color filter, a fluorescence conversion filter and the like, and circuits, wirings and the like required for driving of pixels, as required.

### EXAMPLES

Hereinafter, the present invention will be described in more detail by way of examples and comparative examples, but the present invention is not limited to these examples.

### Preparation Example 1

### Synthesis of Polymer Hole Transporting Compound 1

In an inert atmosphere, 7.54 g of 2,7-bis(1,3,2-dioxaborolan-2-yl)-9,9-dioctylfluorene, 6.54 g of 3,7-dibromo-N-(4-n-butylphenyl)-phenoxazine, 3.4 mg of palladium acetate, 46.7 mg of tri(2-methylphenyl)phosphine, 2.2 g of a 0.74 M toluene solution of a quaternary ammonium chloride catalyst (“Aliquat 336” (registered trademark) manufactured by Aldrich Chemical Co.) and 106 ml of toluene were mixed, and the resulting mixture was heated to 105° C. To this reaction solution, 33 ml of a 2 M aqueous solution of Na₂CO₃ was added dropwise, and the resulting mixture was refluxed for 3 hours. After the reaction, 202 mg of phenylboric acid was added, and the mixture was further refluxed for 3 hours. Next, an aqueous solution of sodium diethyldithiocarbamate was added, and the resulting mixture was stirred at 80° C. for 4 hours. After being cooled, the reactant was washed with 200 ml of water three times, 200 ml of a 3% aqueous solution of acetic acid three times and 200 ml of water three times, and was purified by passing through an alumina column and a silica gel column. The resulting toluene solution was added dropwise to 3 L of methanol and stirred for 3 hours, and the resulting solid was separated by filtration and dried to obtain a polymer hole transporting compound 1. The obtained polymer hole transporting compound 1 had a yield of 8.3 g, a number average molecular weight (Mn) of 2.7×10⁴ on the polystyrene equivalent basis and a weight average molecular weight (Mw) of 5.5×10⁴ on the polystyrene equivalent basis.

The polymer hole transporting compound 1 includes the following repeating unit. n in the following formula represents a polymerization degree.

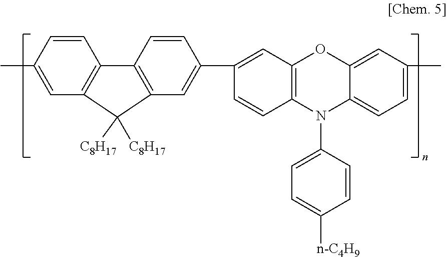

### Preparation Example 2

### Synthesis of Polymer Hole Transporting Compound 2

In a nitrogen atmosphere, 2,7-bis(1,3,2-dioxaborolan-2-y0-9,9-dioctylfluorene (0.64 g, 1.2 mmol) and N,N′-bis(4-bromophenyl)-N,N′-bis(4-n-butylphenyl)-1,4-phenylenediamine (0.75 g, 1.1 mmol) were dissolved in toluene (8.5 g), and to this, tetrakis(triphenylphosphine)palladium (4 mg, 0.0036 mmol) was added, and the resulting mixture was stirred at room temperature for 10 minutes. Thereafter, 4 ml of a 20% aqueous solution of tetraethylammonium hydride was added, and the resulting mixture was heated to 110° C. and reacted for 18 hours while stirring. Thereafter, a solution formed by dissolving bromobenzene (0.28 g, 1.78 mmol) in 1 ml of toluene was added to the reaction solution, and the resulting mixture was stirred at 110° C. for 2 hours. Thereafter, phenylboronic acid (0.22 g, 1.49 mmol) was added to the reaction solution, and the resulting mixture was stirred at 110° C. for 2 hours. After the reaction solution was cooled to 50° C., an organic layer thereof was added dropwise to 200 ml of a mixed solution of methanol and water in proportions of 1:1 and stirred for 1 hour. A precipitate was separated by filtration, washed with methanol and water, and dried under a reduced pressure. Thereafter, the obtained dried substance was dissolved in 50 ml of toluene and purified by passing through a silica column (amount of silica 15 ml). The purified solution was added dropwise to 150 ml of methanol and stirred for 1 hour, and the resulting precipitate was separated by filtration and dried under a reduced pressure to obtain a polymer hole transporting compound 2. The obtained polymer hole transporting compound 2 had a yield of 795 mg, a number average molecular weight (Mn) of 2.7×10⁴ on the polystyrene equivalent basis and a weight average molecular weight (Mw) of 5.7×10⁴.

The polymer hole transporting compound 2 includes the following repeating unit. n in the following formula represents a polymerization degree.

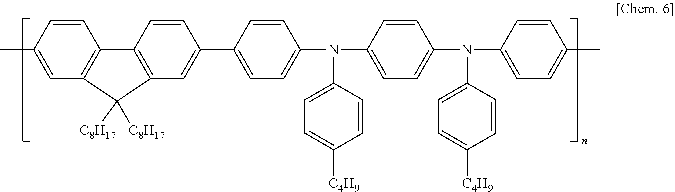

### Preparation Example 3

### Synthesis of Polymer Hole Transporting Compound 3

In an inert atmosphere, 5.28 g of 2,7-bis(1,3,2-dioxaborolan-2-yl)-9,9-dioctylfluorene, 4.55 g of bis(4-bromophenyl)-(4-sec-butylphenyl)-amine, 2 mg of palladium acetate, 15 mg of tri(2-methylphenyl)phosphine, 0.91 g of a 0.74 M toluene solution of a quaternary ammonium chloride catalyst (“Aliquat 336” (registered trademark) manufactured by Aldrich Chemical Co.) and 70 ml of toluene were mixed, and the resulting mixture was heated to 105° C. To this reaction solution, 19 ml of a 17.5% aqueous solution of Na₂CO₃ was added dropwise, and the resulting mixture was refluxed for 19 hours. After the reaction, 0.12 g of phenylboric acid was added, and the mixture was further refluxed for 7 hours. Next, an aqueous solution of sodium N,N-diethyldithiocarbamate (0.44 g/12 ml) was added, and the resulting mixture was stirred at 80° C. for 4 hours. After the reactant was cooled, an organic layer was washed with 40 ml of water, 40 ml of a 3% by weight aqueous solution of acetic acid, and 40 ml of water sequentially, and the organic layer was purified by passing through an alumina/silica gel column. The resulting toluene solution was added dropwise to 1.4 L of methanol, and the resulting solid was separated by filtration and dried to obtain a polymer hole transporting compound 3. The obtained polymer hole transporting compound 3 had a yield of 6.33 g, a number average molecular weight (Mn) of 8.8×10⁴ on the polystyrene equivalent basis and a weight average molecular weight (Mw) of 3.2×10⁵ on the polystyrene equivalent basis.

The polymer hole transporting compound 3 includes the following repeating unit. n in the following formula represents a polymerization degree.

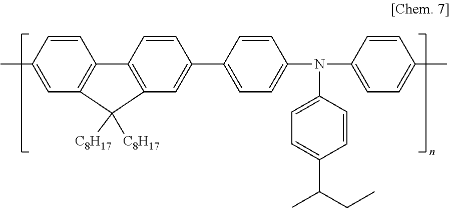

### Example 1

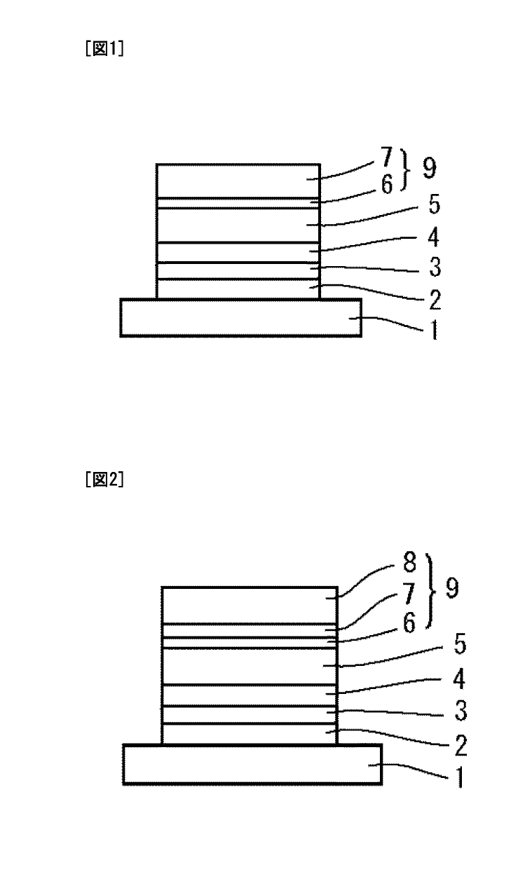

FIG. 1 is a schematic sectional view showing a structure of an organic EL device, which is one embodiment of the present invention.

(1-1: Formation of Hole Injection Layer)

A composition for forming a hole injection layer was applied onto a glass substrate 1 provided with an ITO anode 2 thereon by a spin coating method to obtain a coating film with a film thickness of 60 nm.

The substrate provided with the coating film was heated at 200° C. for 10 minutes to make the coating film insoluble, and then the substrate was naturally cooled to room temperature to obtain a hole injection layer 3. Here, a PEDOT: PSS aqueous solution (poly(3,4-ethylenedioxythiophene)-polystyrenesulfonic acid, trade name “Baytron”), which is available from H.C. Starck-V TECH Ltd., was used for the composition for forming a hole injection layer.

(1-2: Formation of Hole Transporting Layer)

The polymer hole transporting compound 1 and xylene were mixed in such a way that percentage of the polymer hole transporting compound 1 was 0.7% by weight to obtain a composition for forming a hole transporting layer.

A composition for forming a hole transporting layer was applied onto the hole injection layer obtained in the above paragraph (1-1) by a spin coating method to obtain a coating film with a film thickness of 20 nm. The substrate provided with the coating film was heated at 190° C. for 20 minutes to make the coating film insoluble, and then the substrate was naturally cooled to room temperature to obtain a hole transporting layer 4.

(1-3: Formation of Light-Emitting Layer)

A light-emitting polymer material and xylene were mixed in such a way that percentage of the light-emitting polymer material was 1.3% by weight to obtain a composition for forming a light-emitting layer. Here, “Lumation BP361” (trademark) manufactured by SUMATION K.K. was used for the light-emitting polymer material.

The composition for forming a light-emitting layer was applied onto the hole transporting layer of the substrate having an anode, a hole injection layer and a hole transporting layer, obtained in the above paragraph (1-2), by a spin coating method to obtain a coating film with a film thickness of 65 nm. The substrate provided with the coating film was heated at 130° C. for 20 minutes to evaporate a solvent, and then the substrate was naturally cooled to room temperature to obtain a light-emitting layer 5.

(1-4: Formation of Cathode)

A sodium fluoride layer with a film thickness of 4 nm, which is a metal compound layer as a first cathode layer 6 and an aluminum layer with a film thickness of 80 nm, which is a metal layer as a second cathode layer 7 were sequentially formed on the light-emitting layer of the substrate having an anode, a hole injection layer, a hole transporting layer and a light-emitting layer, obtained in the above paragraph (1-3), by a vacuum deposition method using a vacuum deposition apparatus to form a cathode 9.

(1-5: Sealing)

The substrate including lamination obtained in the above paragraph (1-4) was taken out from the vacuum deposition apparatus, and sealed with a sealing glass and a two component epoxy resin (not shown) in a nitrogen atmosphere to obtain a polymer light-emitting device 1.

(1-6: Evaluation)

Voltages of 0 V to 12 V were applied to the polymer light-emitting device 1 obtained in the above paragraph (1-5), and driving voltage when luminance was 1000 cd/m² was measured. Moreover, the luminance half-decay lifetime was measured while applying a constant current at which initial luminance was 2000 cd/m². The results of measurement are shown in Table 1.

### Example 2

A polymer light-emitting device 2 was prepared in the same manner as in Example 1 except that a potassium fluoride layer with a film thickness of 2 nm was formed as the first cathode layer. Driving voltage when luminance was 1000 cd/m² and the luminance half-decay lifetime measured while applying a constant current at which initial luminance was 2000 cd/m² are shown in Table 1.

### Comparative Example 1

A polymer light-emitting device 3 was prepared in the same manner as in Example 1 except that a barium layer with a film thickness of 5 nm was formed as the first cathode layer. Driving voltage when luminance was 1000 cd/m² and the luminance half-decay lifetime measured while applying a constant current at which initial luminance was 2000 cd/m² are shown in Table 1.

### Example 3

A polymer light-emitting device 4 was prepared in the same manner as in Example 1 except that the polymer hole transporting compound 2 was used as the polymer hole transporting compound. Driving voltage when luminance was 1000 cd/m² and the luminance half-decay lifetime measured while applying a constant current at which initial luminance was 2000 cd/m² are shown in Table 1.

### Example 4

A polymer light-emitting device 5 was prepared in the same manner as in Example 3 except that a potassium fluoride layer with a film thickness of 2 nm was formed as the first cathode layer. Driving voltage when luminance was 1000 cd/m² and the luminance half-decay lifetime measured while applying a constant current at which initial luminance was 2000 cd/m² are shown in Table 1.

### Comparative Example 2

A polymer light-emitting device 6 was prepared in the same manner as in Example 3 except that a barium layer with a film thickness of 5 nm was formed as the first cathode layer. Driving voltage when luminance was 1000 cd/m² and the luminance half-decay lifetime measured while applying a constant current at which initial luminance was 2000 cd/m² are shown in Table 1.

### Example 5

A polymer light-emitting device 7 was prepared in the same manner as in Example 1 except that the polymer hole transporting compound 3 was used as the polymer hole transporting compound. Driving voltage when luminance was 1000 cd/m² and the luminance half-decay lifetime measured while applying a constant current at which initial luminance was 2000 cd/m² are shown in Table 1.

### Example 6

A polymer light-emitting device 8 was prepared in the same manner as in Example 5 except that a potassium fluoride layer with a film thickness of 2 nm was formed as the first cathode layer. Driving voltage when luminance was 1000 cd/m² and the luminance half-decay lifetime measured while applying a constant current at which initial luminance was 2000 cd/m² are shown in Table 1.

### Comparative Example 3

A polymer light-emitting device 9 was prepared in the same manner as in Example 5 except that a barium layer with a film thickness of 5 nm was formed as the first cathode layer. Driving voltage when luminance was 1000 cd/m² and the luminance half-decay lifetime measured while applying a constant current at which initial luminance was 2000 cd/m² are shown in Table 1.

### Comparative Example 4

A polymer light-emitting device 10 was prepared in the same manner as in Example 1 except that a light-emitting layer was formed directly on the hole injection layer without forming the hole transporting layer. Driving voltage when luminance was 1000 cd/m² and the luminance half-decay lifetime measured while applying a constant current at which initial luminance was 2000 cd/m² are shown in Table 1.

### Comparative Example 5

A polymer light-emitting device 11 was prepared in the same manner as in Comparative Example 4 except that a potassium fluoride layer with a film thickness of 2 nm was formed as the first cathode layer. Driving voltage when luminance was 1000 cd/m² and the luminance half-decay lifetime measured while applying a constant current at which initial luminance was 2000 cd/m² are shown in Table 1.

### Comparative Example 6

A polymer light-emitting device 12 was prepared in the same manner as in Comparative Example 4 except that a barium layer with a film thickness of 5 nm was formed as the first cathode layer. Driving voltage when luminance was 1000 cd/m² and the luminance half-decay lifetime measured while applying a constant current at which initial luminance was 2000 cd/m² are shown in Table 1.

TABLE 1

| | Hole | First | | Second | | | |
|---|---|---|---|---|---|---|---|
| | transporting | cathode | Film | cathode | Driving | Luminance | Lifetime |
| | layer | layer | thickness | layer | voltage | half-decay | multiplication |
| | material | material | [nm] | material | [V] | lifetime [h] | factor |
| Comparative | Polymer hole | Ba | 5 nm | Al | 4.8 | 35 | 1.0 |
| Example 1 | transporting | | | | | | |
| Example 1 | compound 1 | NaF | 4 nm | Al | 4.2 | 73 | 2.1 |
| Example 2 | | KF | 2 nm | Al | 3.8 | 172 | 4.9 |
| Comparative | Polymer hole | Ba | 5 nm | Al | 5.5 | 28 | 1.0 |
| Example 2 | transporting | | | | | | |
| Example 3 | compound 2 | NaF | 4 nm | Al | 4.8 | 51 | 1.8 |
| Example 4 | | KF | 2 nm | Al | 4.2 | 98 | 3.5 |
| Comparative | Polymer hole | Ba | 5 nm | Al | 5.0 | 16 | 1.0 |
| Example 3 | transporting | | | | | | |
| Example 5 | compound 3 | NaF | 4 nm | Al | 4.3 | 36 | 2.3 |
| Example 6 | | KF | 2 nm | Al | 4.1 | 122 | 7.7 |
| Comparative | Without hole | Ba | 5 nm | Al | 5.0 | 10 | 1.0 |
| Example 6 | transporting | | | | | | |
| Comparative | layer | NaF | 4 nm | Al | 4.1 | 10 | 1.1 |
| Example 4 | | | | | | | |
| Comparative | | KF | 2 nm | Al | 3.7 | 19 | 1.9 |
| Example 5 | | | | | | | |

In the table, the lifetime multiplication factor of Example 1 refers to the luminance half-decay lifetime of the polymer light-emitting device of Example 1 divided by the luminance half-decay lifetime of the polymer light-emitting device of Comparative Example 1, and the lifetime multiplication factor of Example 2 refers to the luminance half-decay lifetime of the polymer light-emitting device of Example 2 divided by the luminance half-decay lifetime of the polymer light-emitting device of Comparative Example 1. The lifetime multiplication factor of Example 3 refers to the luminance half-decay lifetime of the polymer light-emitting device of Example 3 divided by the luminance half-decay lifetime of the polymer light-emitting device of Comparative Example 2, and the lifetime multiplication factor of Example 4 refers to the luminance half-decay lifetime of the polymer light-emitting device of Example 4 divided by the luminance half-decay lifetime of the polymer light-emitting device of Comparative Example 2. The lifetime multiplication factor of Example 5 refers to the luminance half-decay lifetime of the polymer light-emitting device of Example 5 divided by the luminance half-decay lifetime of the polymer light-emitting device of Comparative Example 3, and the lifetime multiplication factor of Example 6 refers to the luminance half-decay lifetime of the polymer light-emitting device of Example 6 divided by the luminance half-decay lifetime of the polymer light-emitting device of Comparative Example 3. The lifetime multiplication factor of Comparative Example 4 refers to the luminance half-decay lifetime of the polymer light-emitting device of Comparative Example 4 divided by the luminance half-decay lifetime of the polymer light-emitting device of Comparative Example 6, and the lifetime multiplication factor of Comparative Example 5 refers to the luminance half-decay lifetime of the polymer light-emitting device of Comparative Example 5 divided by the luminance half-decay lifetime of the polymer light-emitting device of Comparative Example 6.

(Driving Voltage)

As is apparent when comparing Examples 1 to 2 with Comparative Example 1, comparing Examples 3 to 4 with Comparative Example 2, and comparing Examples 5 to 6 with Comparative Example 3, the polymer light-emitting devices of the present invention, which use sodium fluoride or potassium fluoride as the first cathode material, have a lower driving voltage to emit light at a luminance of 1000 cd/m² than those of polymer light-emitting devices which use barium as the first cathode material.

(Luminance Half-Decay Lifetime)

As is apparent when comparing Examples 1 to 6 with Comparative Examples 4 to 6, the polymer light-emitting devices of the present invention, which use the polymer compound including a repeating unit represented by the formula (1) as the hole transporting layer, have a significantly longer luminance half-decay lifetime than those of Comparative Examples 4 to 6 which do not have the hole transporting layer.

Further, in the case of the polymer light-emitting device of the present invention, which uses the polymer compound including a repeating unit represented by the formula (1) as the hole transporting layer, the lifetime multiplication factors of the polymer light-emitting devices using sodium fluoride or potassium fluoride as the first cathode material based on the polymer light-emitting device using barium as the first cathode material are significantly larger than the lifetime multiplication factors of the polymer light-emitting devices which do not include the hole transporting layer and use sodium fluoride or potassium fluoride as the first cathode material based on the polymer light-emitting device using barium as the first cathode material. For example, when potassium fluoride is used as the first cathode material, the effect of lifetime multiplying of the polymer light-emitting device of Comparative Example 5, which do not include the hole transporting layer, based on the polymer light-emitting device of Comparative Example 6, is 1.9, but the effects of lifetime multiplying of the polymer light-emitting devices of Examples 1, 3 and 5 of the present invention, which use the polymer compounds including a repeating unit represented by the formula (1) as the hole transporting layer, are 4.9, 3.5 and 7.7, respectively.

### Preparation Example 4

### Synthesis of Polymer Hole Transporting Compound 4

The following reaction step 1 represents the preparation of a triarylamine compound containing a crosslinkable benzocyclobutane functional group, and a polymerization reaction for preparing the polymer hole transporting compound 4 containing 5 mol % of crosslinkable conjugated diarylamine functional group and 95 mol % of non-crosslinkable diarylamine functional unit.

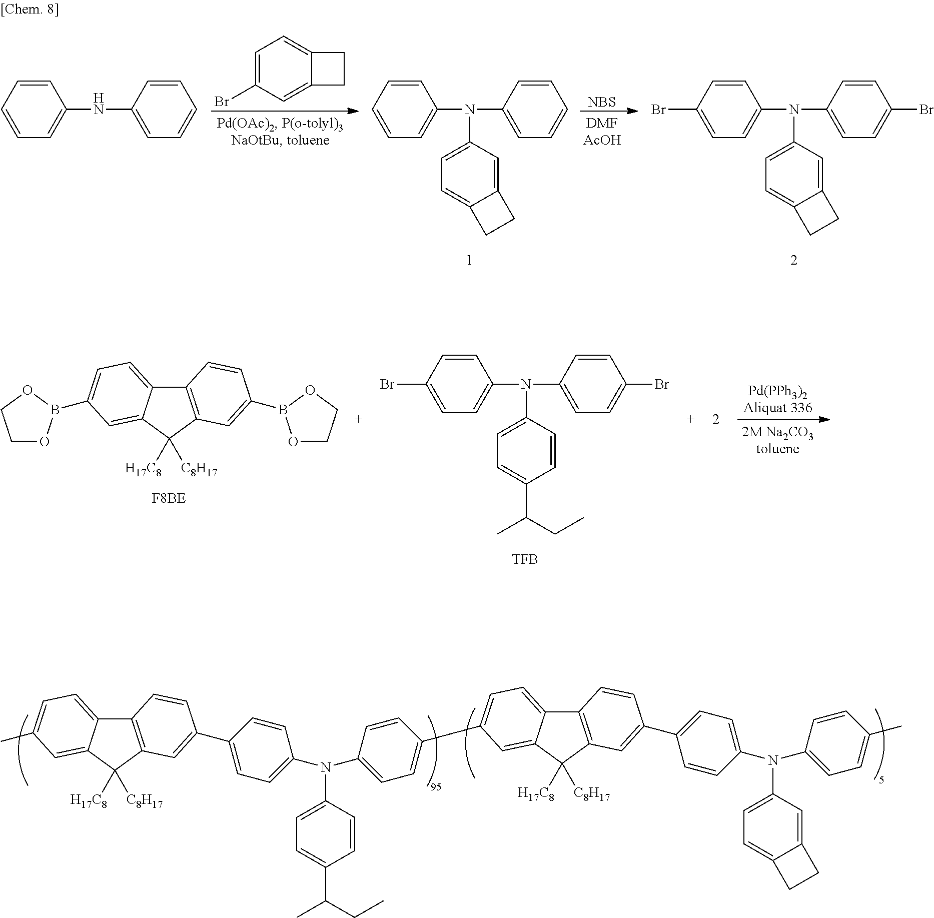

In the above steps, F8BE is 2,7-bis(1,3,2-dioxaborolan-2-yl)-9,9-dioctylfluorene, and TFB is bis(4-bromophenyl)-(4-sec-butylphenyl)-amine.

(4-A: Synthesis of Diphenylbenzocyclobutaneamine)

To a 500-ml, three-necked round-bottomed flask equipped with a mechanical stirrer, a nitrogen inlet, and a reflux condenser (with a nitrogen outlet), palladium (II) acetate (196 mg, 1.20 mmol) and tri(o-tolyl)phosphine (731 mg, 2.40 mmol) were added to 100 ml of toluene. The resulting mixture was stirred at room temperature under nitrogen until the palladium catalyst was dissolved and the solution turned yellow. Diphenyl amine (20.0 g, 118 mmol), bromobenzocyclobutane (23.8 g, 130 mmol) and 400 ml of toluene were added, followed by sodium t-butoxide (22.8 g, 237 mmol). Upon addition of sodium t-butoxide, the reactant turned black. The reactant was refluxed for 22 hours by heating under nitrogen. The reaction was stopped by addition of 30 ml of a 1 M aqueous solution of HCl. A toluene layer was washed with 2 M Na₂CO₃ (100 ml) and then the toluene solution was passed through basic alumina. When toluene was evaporated, a yellow oil was obtained. The product was precipitated by stirring the oil with isopropanol. The precipitated solids were collected and recrystallized from hot isopropanol. ¹H NMR (CDCl₃-d) δ: 7.3-6.8 (m, 13H, Ar), 3.12 (d, 4H, —CH₂CH₂—).

(4-B: di(4-bromophenyl)benzocyclobutane Amine)

In a 250-ml round-bottomed flask, diphenylbenzocyclobutaneamine (8.00 g, 29.5 mmol) was added to 100 ml of dimethylformamide (DMF) containing 5 drops of glacial acetic acid. N-bromosuccinimide (NBS, 10.5 g, 60.7 mmol, 1.97 eq.) was added while stirring to the resulting solution. After stirring for 5 hours, the reaction was stopped by pouring the reaction mixture into 600 ml of methanol/water (1:1 by volume). A gray solid was recovered by filtration and recrystallized from isopropanol. ¹H NMR (CDCl₃-d) δ: 7.3 (d, 4H, Ar), 7.0 (d, 4H, Ar), 6.95 (t, Ar), 6.8 (s, Ar), 3.12 (d, 4H, —CH₂CH₂—).

(4-C: Synthesis of Polymer Hole Transporting Compound 4)

In a 1-L three-necked round-bottomed flask equipped with a reflux condenser and an overhead stirrer, the following monomers: F8BE (3.863 g, 7.283 mmol) and TFB (3.177 g, 6.919 mmol); and di(4-bromophenyl)benzocyclobutane amine (156.3 mg, 0.364 mmol) obtained in the above Preparation Example (4-B) were added. A 0.74 M toluene solution of a quaternary ammonium chloride catalyst (trade name “Aliquat 336”, obtained from Sigma-Aldrich Corp., 3.1 ml) and subsequently 50 ml of toluene were added. After a PdCl₂ (PPh₃)₂ catalyst (4.9 mg) was added, the resulting mixture was stirred in an oil bath (105° C.) until all monomers were dissolved (about 15 minutes). An aqueous solution of sodium carbonate (2.0 M, 14 ml) was added, and the reactant was stirred for 16.5 hours in an oil bath (105° C.). Next, phenylboronic acid (0.5 g) was added, and the reactant was stirred for 7 hours. A water layer was removed and an organic layer was washed with 50 ml of water. The organic layer was returned to the reaction flask, and to this, 0.75 g of sodium diethyldithiocarbamate and 50 ml of water were added. The reactant was stirred for 16 hours in an oil bath (85° C.). A water layer was removed, and an organic layer was washed with 100 ml of water three times and passed through a silica gel and basic alumina column. Then, a toluene/polymer solution was precipitated in methanol twice, and the resulting polymer compound was dried at 60° C. under vacuum to obtain a polymer hole transporting compound 4. The obtained polymer hole transporting compound 4 had a yield of 4.2 g (82%), a weight average molecular weight (Mw) of 124,000 on the polystyrene equivalent basis and a dispersity (Mw/Mn) of 2.8.

The polymer hole transporting compound 4 includes the following repeating unit. A numerical subscription of parentheses in the following formula represents mol % of the repeating unit.

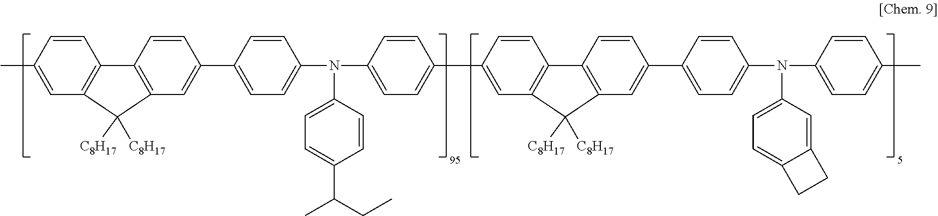

### Example 7

FIG. 1 is a schematic sectional view showing a structure of an organic EL device, which is one embodiment of the present invention.

(2-1: Formation of Hole Injection Layer) A composition for forming a hole injection layer was applied onto a glass substrate 1 provided with an ITO anode 2 thereon by a spin coating method to obtain a coating film with a film thickness of 60 nm.

The substrate provided with the coating film was heated at 200° C. for 10 minutes to make the coating film insoluble, and then the substrate was naturally cooled to room temperature to obtain a hole injection layer 3. Here, a PEDOT: PSS aqueous solution (poly(3,4-ethylenedioxythiophene)-polystyrenesulfonic acid, trade name “Baytron”), which is available from H. C. Starck-V TECH Ltd., was used for the composition for forming a hole injection layer.

(2-2: Formation of Hole Transporting Layer)

The polymer hole transporting compound 4 and xylene were mixed in such a way that percentage of the polymer hole transporting compound 4 was 0.7% by weight to obtain a composition for forming a hole transporting layer.

The composition for forming a hole transporting layer was applied onto the hole injection layer obtained in the above paragraph (2-1) by a spin coating method to obtain a coating film with a film thickness of 20 nm. The substrate provided with the coating film was heated at 190° C. for 20 minutes to make the coating film insoluble, and then the substrate was naturally cooled to room temperature to obtain a hole transporting layer 4.

(2-3: Formation of Light-Emitting Layer)

A light-emitting polymer material and xylene were mixed in such a way that percentage of the light-emitting polymer material was 1.3% by weight to obtain a composition for forming a light-emitting layer. Here, “Lumation BP361” (trademark) manufactured by SUMATION K.K. was used for the light-emitting polymer material.

The composition for forming a light-emitting layer was applied onto the hole transporting layer of the substrate having an anode, a hole injection layer and a hole transporting layer, obtained in the above paragraph (2-2), by a spin coating method to obtain a coating film with a film thickness of 70 nm. The substrate provided with the coating film was heated at 130° C. for 20 minutes to evaporate a solvent, and then the substrate was naturally cooled to room temperature to obtain a light-emitting layer 5.

(2-4: Formation of Cathode)

A sodium fluoride layer with a film thickness of 2 nm, which is a metal compound layer as a first cathode layer 6 and an aluminum layer with a film thickness of 80 nm, which is a metal layer as a second cathode layer 7 were sequentially formed on the light-emitting layer of the substrate having an anode, a hole injection layer, a hole transporting layer and a light-emitting layer, obtained in the above paragraph (2-3), by a vacuum deposition method using a vacuum deposition apparatus to form a cathode 9.

(2-5: Sealing)

The substrate including lamination obtained in the above paragraph (2-4) was taken out from the vacuum deposition apparatus, and sealed with a sealing glass and a two component epoxy resin (not shown) in a nitrogen atmosphere to obtain a polymer light-emitting device 13.

(2-6: Evaluation)

Voltages of 0 V to 12 V were applied to the polymer light-emitting device 13 obtained in the above paragraph (2-5), and driving voltage when luminance was 1000 cd/m² was measured. Moreover, the luminance half-decay lifetime was measured while applying a constant current at which initial luminance was 2000 cd/m². The results of measurement are shown in Table 2.

### Example 8

A polymer light-emitting device 14 was prepared in the same manner as in Example 7 except that a sodium fluoride layer with a film thickness of 3 nm was formed as the first cathode layer. Driving voltage when luminance was 1000 cd/m² and the luminance half-decay lifetime measured while applying a constant current at which initial luminance was 2000 cd/m² are shown in Table 2.

### Example 9

A polymer light-emitting device 15 was prepared in the same manner as in Example 7 except that a sodium fluoride layer with a film thickness of 4 nm was formed as the first cathode layer. Driving voltage when luminance was 1000 cd/m² and the luminance half-decay lifetime measured while applying a constant current at which initial luminance was 2000 cd/m² are shown in Table 2.

### Example 10

A polymer light-emitting device 16 was prepared in the same manner as in Example 7 except that a sodium fluoride layer with a film thickness of 6 nm was formed as the first cathode layer. Driving voltage when luminance was 1000 cd/m² and the luminance half-decay lifetime measured while applying a constant current at which initial luminance was 2000 cd/m² are shown in Table 2.

### Example 11

A polymer light-emitting device 17 was prepared in the same manner as in Example 7 except that a potassium fluoride layer with a film thickness of 4 nm was formed as the first cathode layer. Driving voltage when luminance was 1000 cd/m² and the luminance half-decay lifetime measured while applying a constant current at which initial luminance was 2000 cd/m² are shown in Table 2.

### Example 12

A polymer light-emitting device 18 was prepared in the same manner as in Example 7 except that a rubidium fluoride layer with a film thickness of 4 nm was formed as the first cathode layer. Driving voltage when luminance was 1000 cd/m² and the luminance half-decay lifetime measured while applying a constant current at which initial luminance was 2000 cd/m² are shown in Table 2.

### Example 13

A polymer light-emitting device 19 was prepared in the same manner as in Example 7 except that a cesium fluoride layer with a film thickness of 4 nm was formed as the first cathode layer. Driving voltage when luminance was 1000 cd/m² and the luminance half-decay lifetime measured while applying a constant current at which initial luminance was 2000 cd/m² are shown in Table 2.

### Comparative Example 7

A polymer light-emitting device 20 was prepared in the same manner as in Example 7 except that a lithium fluoride layer with a film thickness of 4 nm was formed as the first cathode layer. Driving voltage when luminance was 1000 cd/m² and the luminance half-decay lifetime measured while applying a constant current at which initial luminance was 2000 cd/m² are shown in Table 2.

### Comparative Example 8

A polymer light-emitting device 21 was prepared in the same manner as in Example 7 except that a sodium fluoride layer with a film thickness of 3 nm was formed as the first cathode layer and that a silver layer with a film thickness of 80 nm was formed as the second cathode layer. Driving voltage when luminance was 1000 cd/m² and the luminance half-decay lifetime measured while applying a constant current at which initial luminance was 2000 cd/m² are shown in Table 2.

TABLE 2

| | First | | Second | | |
|---|---|---|---|---|---|
| | cathode | | cathode | Driving | Luminance |
| | layer | Film | layer | voltage | half-decay |
| | material | thickness | material | [V] | lifetime [hr] |
| Example 7 | NaF | 2 nm | Al | 4.3 | 135 |
| Example 8 | NaF | 3 nm | Al | 4.5 | 135 |
| Example 9 | NaF | 4 nm | Al | 5.2 | 50.5 |
| Example 10 | NaF | 6 nm | Al | 8.8 | 3 |
| Example 11 | KF | 4 nm | Al | 4.1 | 163 |
| Example 12 | RbF | 4 nm | Al | 3.9 | 155 |
| Example 13 | CsF | 4 nm | Al | 3.8 | 149 |
| Comparative | LiF | 4 nm | Al | 7.7 | 6 |
| Example 7 | | | | | |
| Comparative | NaF | 3 nm | Ag | >12 | Unmeasurable |
| Example 8 | | | | | |

### Preparation Example 5

(Synthesis of Polymer Hole Transporting Compound 5)

2,7-Dibromo-9,9-dioctylfluorene (17.8 g, 33.6 mmol), 5,5′-dibromo-2,2′-bithiophene (11.7 g, 36.2 mmol), dichlorobigtriphenylphosphine)palladium (II) (0.02 g, 0.03 mmol), and tricaprylyl methyl ammonium chloride (trade name: Aliquat 336, 4.01 g, 20.0 mmol) were dissolved in 300 ml of toluene previously bubbled with nitrogen and heated to 55° C. To this, 60 ml of a 2 mol/l aqueous solution of sodium carbonate was added dropwise, and the resulting mixture was refluxed at 105° C. for 24 hours by heating. Then, to a system in which this reactant was present, phenylboric acid (2.00 g, 16.4 mmol) and 60 ml of THF were added, and the resulting mixture was further refluxed for 24 hours by heating. Toluene was added to the reactant to dilute, and the diluted reactant was washed with ion-exchange water of 60° C. three times. To this, sodium N,N-diethyldithiocarbamate trihydrate and ion-exchange water were added, and the resulting mixture was stirred at 80° C. for 16 hours. A water layer was removed, and then the reactant was washed with 2% by weight acetic acid of 60° C. three times and further washed with ion-exchange water of 60° C. three times. The organic layer was added dropwise to methanol, and a precipitated deposit was separated by filtration, washed with methanol, and then vacuum dried. The resulting solid was dissolved in mesitylene of 80° C. and passed through a column packed with celite, silica gel and neutral alumina. The resulting solution was concentrated, and then added dropwise to methanol, and a precipitated deposit was separated by filtration, and washed with methanol two times, with acetone two times and further with methanol two times, and vacuum dried to obtain a polymer hole transporting compound 5. The obtained polymer hole transporting compound 5 had a yield of 13.8 g, a number average molecular weight Mn of 1.8×10⁴ on the polystyrene equivalent basis and a weight average molecular weight Mw of 3.4×10⁴ on the polystyrene equivalent basis.

The polymer hole transporting compound 5 includes the following repeating unit. n in the following formula represents a polymerization degree.

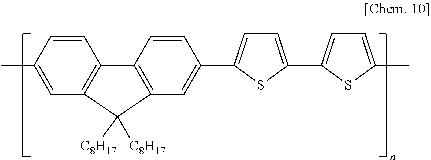

### Comparative Example 9

A polymer light-emitting device 22 was prepared in the same manner as in Example 7 except that the polymer hole transporting compound 5 was used in place of the polymer hole transporting compound 4, and that the polymer hole transporting compound 5 and chloroform were mixed in such a way that percentage of the polymer hole transporting compound 5 was 0.6% by weight to obtain a composition for forming a hole transporting layer.

Driving voltage when luminance was 1000 cd/m² and the luminance half-decay lifetime measured while applying a constant current at which initial luminance was 2000 cd/m² are shown in Table 3.

### Example 14

FIG. 2 is a schematic sectional view showing a structure of an organic EL device, which is another embodiment of the present invention.

As shown in FIG. 2, a polymer light-emitting device 23 was prepared in the same manner as in Example 7 except that by a vacuum deposition method, a sodium fluoride layer with a film thickness of 4 nm, which is a metal compound layer as a first cathode layer 6, a magnesium layer with a film thickness of 5 nm, which is an alkaline earth metal layer as a second cathode layer 7 and an aluminum layer with a film thickness of 80 nm, which is a conductive substance layer as a third cathode layer 8 were sequentially formed to form a cathode 9.

Driving voltage when luminance was 1000 cd/m² and the luminance half-decay lifetime measured while applying a constant current at which initial luminance was 2000 cd/m² are shown in Table 3.

TABLE 3

| | Hole | First cathode | Second | Third cathode | | |
|---|---|---|---|---|---|---|
| | transporting | layer material | cathode layer | layer material | Driving | Luminance |
| | layer | (metal | material | (conductive | voltage | half-decay |
| | material | compound) | (metal) | substance) | [V] | lifetime [h] |
| Comparative | Without a | NaF | Al | none | 4.1 | 10 |
| Example 4 | hole | (film thickness | (film | | | |
| | transporting | 4 nm) | thickness 80 nm) | | | |
| | layer | | | | | |
| Comparative | Polymer | NaF | Al | none | 6.0 | 32 |
| Example 9 | hole | (film thickness | (film | | | |
| | transporting | 4 nm) | thickness 80 nm) | | | |
| | compound 5 | | | | | |
| Example 9 | Polymer | NaF | Al | none | 5.2 | 50.5 |
| | hole | (film thickness | (film | | | |
| | transporting | 4 nm) | thickness 80 nm) | | | |
| | compound 4 | | | | | |
| Example 14 | Polymer | NaF | Mg | Al | 3.8 | 122 |
| | hole | (film thickness | (film | (film | | |
| | transporting | 4 nm) | thickness 5 nm) | thickness 80 nm) | | |
| | compound 4 | | | | | |

### DESCRIPTION OF THE REFERENCE NUMERALS AND SYMBOLS

1 . . . glass substrate
2 . . . ITO anode
3 . . . hole injection layer
4 . . . hole transporting layer
5 . . . light-emitting layer
6 . . . first cathode layer
7 . . . second cathode layer
8 . . . third cathode layer
9 . . . cathode

1. A polymer light-emitting device including a cathode, an anode, and a functional layer containing a polymer compound and a light-emitting layer containing an organic polymer light-emitting compound arranged between the cathode and the anode, wherein
the cathode comprises a first cathode layer and a second cathode layer in this order from the light-emitting layer side, the first cathode layer contains one or more metal compounds selected from the group consisting of sodium fluoride, potassium fluoride, rubidium fluoride and cesium fluoride, and the second cathode layer contains one or more metals selected from the group consisting of alkaline earth metals and aluminum, and wherein
the polymer compound contained in the functional layer is a polymer compound including a repeating unit represented by the formula (1): 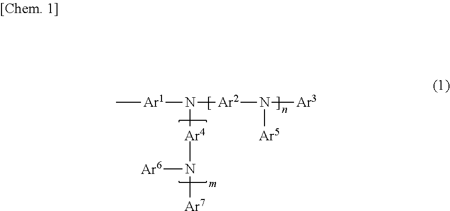
wherein Ar¹, Ar², Ar³ and Ar⁴ are the same or different and each represent an arylene group optionally having a substituent or a divalent heterocyclic group optionally having a substituent, Ar⁵, Ar⁶ and Ar⁷ are the same or different and each represent an aryl group optionally having a substituent or a monovalent heterocyclic group optionally having a substituent, n and m are the same or different and each represent 0 or 1, and when n is 0, a carbon atom contained in Ar¹ may be directly bound to a carbon atom contained in Ar³, or may be bound to a carbon atom contained in Ar³ via an oxygen atom or a sulfur atom.

2. The polymer light-emitting device according to claim 1, wherein the polymer compound contained in the functional layer is an organic polymer compound further including a repeating unit represented by the formula: 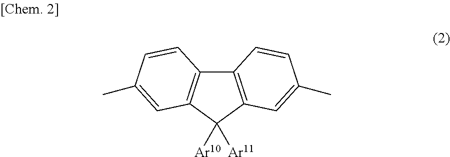
wherein Ar¹⁰ and Ar¹¹ are the same or different and each represent an alkyl group, an aryl group optionally having a substituent or a monovalent heterocyclic group optionally having a substituent.

3. The polymer light-emitting device according to claim 1, wherein the alkaline earth metal is magnesium or calcium.

4. The polymer light-emitting device according to claim 1, wherein the cathode comprises a first cathode layer, a second cathode layer and a third cathode layer in this order from the light-emitting layer side, the second cathode layer contains one or more alkaline earth metals selected from the group consisting of magnesium and calcium, and the third cathode layer is made of a conductive substance.

5. The polymer light-emitting device according to claim 1, wherein the film thickness of the first cathode layer is not less than 0.5 nm and less than 6 nm.

6. The polymer light-emitting device according to claim 1, wherein the functional layer is a hole transporting layer disposed between the anode and the light-emitting layer, and the polymer compound is a hole transporting compound.

7. The polymer light-emitting device according to claim 1, wherein m and n each represent 0, and Ar¹, Ar³ and Ar⁷ are the same or different and each represent a phenyl group optionally having a substituent.

8. The polymer light-emitting device according to claim 2, wherein Ar¹⁰ and Ar¹¹ are the same or different and each represent an alkyl group having 5 to 8 carbon atoms.

9. A polymer light-emitting display comprising the polymer light-emitting device according to claim 1 as a pixel unit.
